(19) United States
(12) Patent Application Publication
(10) Pub. No.: US 2025/0081747 A1
(43) Pub. Date: Mar. 6, 2025

(54) DISPLAY PANEL AND DISPLAY DEVICE

(71) Applicants: Hefei Visionox Technology Co., Ltd., Hefei (CN); KunShan Go Visionox Opto Electronics Co., Ltd, Kunshan (CN)

(72) Inventors: Xiaoxi SUN, Hefei (CN); Xuejing ZHU, Hefei (CN); Mingxing LIU, Hefei (CN)

(73) Assignees: Hefei Visionox Technology Co., Ltd., Hefei (CN); KunShan Go-Visionox Opto Electronics Co., Ltd, Kunshan (CN)

(21) Appl. No.: 18/679,994

(22) Filed: May 31, 2024

(30) Foreign Application Priority Data
Aug. 28, 2023 (CN) 202311091555.7
Aug. 28, 2023 (CN) 202311091950.5

(51) Int. Cl. H10K 59/122; H10K 59/131; H10K 59/80

(52) U.S. Cl. CPC H10K 59/122; H10K 59/131; H10K 59/873

(57) ABSTRACT

A display panel and a display device. The display panel has a first area. The display panel includes a substrate, an isolation structure and a light-emitting functional layer. The isolation structure is arranged on a side of the substrate and positioned in the first area. The isolation structure encloses to form a plurality of opening structures and includes a conductive material. The light-emitting functional layer is arranged on the side of the substrate and positioned at least in the first area. The light-emitting functional layer includes a plurality of light-emitting structures respectively provided in the plurality of opening structures. First signal lines are positioned on a side of the isolation structure along a first direction. The first signal lines are electrically connected to the conductive material of the isolation structure. The first direction is parallel to a plane of the substrate.

### CROSS-REFERENCE TO RELATED APPLICATION

The present application is based upon and claims the priority to Chinese patent application No. 202311091555.7 filed on Aug. 28, 2023 and Chinese patent application No. 202311091950.5 filed on Aug. 28, 2023, both of which are incorporated herein by reference in their entireties.

### TECHNICAL FIELD

The present application relates to the field of display apparatus, and particularly, relates to a display panel and a display device.

### BACKGROUND

Planar display panels, such as Organic Light-emitting Diode (OLED) panels and display panels using Light-emitting Diode (LED) devices etc., have been widely used in mobile phones, televisions, personal digital assistants, digital cameras, laptop computers, desktop computers and other consumer electronic products, due to their advantages of high picture quality, power saving, thin bodies and wide application ranges, and have become a main stream of display devices.

### SUMMARY

Embodiments of the application provides a display panel and a display device, in which a bezel size of the display panel or the display device can be reduced.

In a first aspect, an embodiment of the present application provides a display panel. The display panel has a first area and includes a substrate, an isolation structure and a light-emitting functional layer.

The isolation structure is arranged on a side of the substrate and positioned at least in the first area, the isolation structure encloses to form a plurality of opening structures and includes a conductive material; the light-emitting functional layer is arranged on the side of the substrate and positioned in the first area, and includes a plurality of light-emitting structures respectively provided in the plurality of opening structures; and the first signal lines are positioned on a side of the isolation structure along a first direction, the first signal lines are electrically connected to the conductive material of the isolation structure, and the first direction is parallel to a plane of the substrate.

In a second aspect, an embodiment of the present application provides a display panel having a first area and a second area surrounding a periphery of the first area. The display panel includes a substrate, an isolation structure, a light-emitting functional layer, a light-emitting control circuit and a blocking portion.

The isolation structure is arranged on a side of the substrate and encloses to form a plurality of opening structures; the light-emitting functional layer is arranged on the side of the substrate and positioned in the first area, the light-emitting functional layer includes a plurality of light-emitting structures respectively provided in the plurality of opening structures; the light-emitting control circuit is positioned in the second area; and the blocking portion is arranged in the second area, and at least a part of the blocking portion is positioned on a side of the gate driving circuit facing away from the substrate.

In a third aspect, an embodiment of the present application provides a display panel having a first area and a second area surrounding a periphery of the first area. The display panel includes a substrate, an isolation structure, a light-emitting functional layer, a gate driving circuit and a blocking portion.

The isolation structure is arranged on a side of the substrate and encloses to form a plurality of opening structures; the light-emitting functional layer is arranged on the side of the substrate and positioned in the first area, the light-emitting functional layer includes a plurality of light-emitting structures respectively provided in the plurality of opening structures; the gate driving circuit is positioned in the second area; and the blocking portion is arranged in the second area, and at least a part of an orthographic projection of the blocking portion on the substrate overlaps with an orthographic projection of the gate driving circuit on the substrate.

In a fourth aspect, an embodiment of the present application provides a display panel having a first area and a second area surrounding a periphery of the first area. The display panel includes a substrate; an isolation structure arranged on a side of the substrate, the isolation structure enclosing to form a plurality of opening structures; a light-emitting functional layer arranged on the side of the substrate and positioned in the first area, the light-emitting functional layer including a plurality of light-emitting structures respectively provided in the plurality of opening structures; a gate driving circuit positioned in the second area; and a blocking portion arranged in the second area, and an orthographic projection of the blocking portion on the substrate is adjacent to an orthographic projection of the gate driving circuit on the substrate.

In a fifth aspect, an embodiment of the present application provides a display panel having a first area and a second area, the first area including a display area and the second area including a bottom bezel area. The display panel includes a substrate; an isolation structure arranged on a side of the substrate and positioned at least in the first area, the isolation structure enclosing to form a plurality of opening structures and the isolation structure including a conductive material; a light-emitting functional layer arranged on the side of the substrate and positioned in the first area, the light-emitting functional layer including a plurality of light-emitting structures respectively provided in the plurality of opening structures; and first signal lines positioned on a side of the isolation structure along a first direction, the first signal lines electrically connected to the conductive material of the isolation structure, and the first direction being a direction from the display area to the bottom bezel area.

In a sixth aspect, an embodiment of the present application provides a display device, including the display panel of any one of the above embodiments.

In the display panel and the display device provided by the embodiments of the present application, rather than arranged around the first area, the first signal lines are positioned on a side of the first area along the first direction, and transmit signals to different positions in the first area by means of the isolation structure. In particular, since the isolation structure is distributed at various locations throughout the first area, and is provided with a conductive material therein to transmit particular signals. Therefore, there is no need for the first signal lines to be arranged around the first area, as long as the first signal lines are arranged on a side of the isolation structure along the first direction, and are electrically connected to the isolation structure. As such, power supply signals in the first signal lines can be transmitted to different positions in the first area by means of the isolation structure, thereby satisfying the need for signal transmission. Furthermore, since the first signal lines are positioned on the side of the isolation structure along the first direction, rather than in an annular structure, it contributes to reduce the bezel size of the display panel and improve the display effect.

### BRIEF DESCRIPTION OF THE DRAWINGS

In order to explain technical solutions of embodiments of the application more clearly, drawings used in the embodiments of the present application will be described briefly below. For a person of ordinary skills in the art, it would be possible to obtain other drawings according to these drawings, without involving any inventive effort.

FIG. 1 is a schematic structure diagram of a display panel according to an embodiment of the present application;

FIG. 2 is a schematic diagram showing a relative position relationship between an isolation structure and first signal lines at region Q in FIG. 1;

FIG. 3 is a schematic sectional structure view at A-A in FIG. 2;

FIG. 4 is a schematic sectional structure view of another display panel at A-A according to an embodiment of the present application;

FIG. 5 is a schematic sectional structure view of another display panel at A-A according to an embodiment of the present application;

FIG. 6 is a schematic diagram showing a relative position relationship between an isolation structure and first signal lines at region Q of another display panel according to an embodiment of the present application;

FIG. 7 is a schematic sectional structure view at B-B in FIG. 2;

FIG. 8 is a schematic sectional structure view of another display panel at B-B according to an embodiment of the present application;

FIG. 9 is a schematic sectional structure view of another display panel at B-B according to an embodiment of the present application;

FIG. 10 is a schematic sectional structure view of another display panel at B-B according to an embodiment of the present application;

FIG. 11 is a schematic sectional structure view of another display panel at B-B according to an embodiment of the present application; and

FIG. 12 is a schematic structure diagram of a display device according to an embodiment of the present application.

### DESCRIPTION OF REFERENCE SIGNS

10, substrate;
20, isolation structure; 21, opening structure; 22, first isolation portion; 23, second isolation portion; 24, third isolation portion; 25, first insulation portion; 26, first isolation structure; 27, second isolation structure; 28, insulation structure;
31, light-emitting structure;
40, first electrode layer; 41, first electrode;
50, second electrode layer; 51, second electrode;
60, first signal line;
71, first encapsulation layer; 711, first encapsulation portion; 72, second encapsulation layer; 73, third encapsulation layer;
80, pixel definition layer; 81, pixel defining portion; 82, pixel opening;
90, blocking portion; 91, second insulation portion; 92, blocking past;
D1, scanning driving circuit; D2, light-emitting control circuit
IC, driving chip;
A1, first area; A2, second area; A21, first subarea; A22, second subarea; X, first direction; Y, second direction; Z, thickness direction.

### DETAILED DESCRIPTION

As the user demand for an increased display size increases, the problem of narrowing a display panel bezel size becomes more prominent. In the related art, it is generally necessary to arrange a variety of circuit structures at the position of a display panel's bezel to satisfy a requirement of normal operation of the display panel. However, due to these circuit structures, it is difficult to reduce the size of the display panel's bezel, and if the bezel size is reduced forcibly, the display panel will undergo problems such as display abnormality or reduced display quality, and the like.

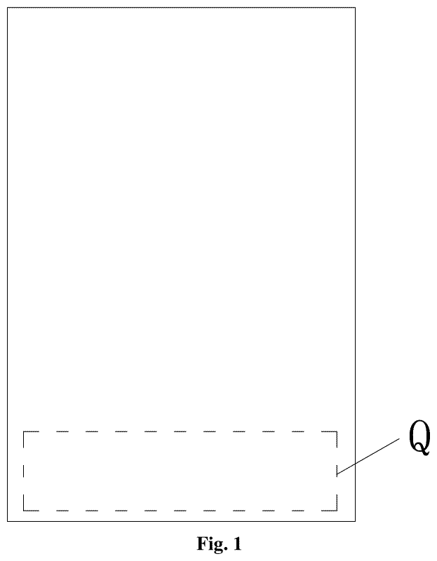

With regard to the above-mentioned problems, in a first aspect, as shown in FIG. 1-FIG. 3, an embodiment of the application provides a display panel. The display panel has a first area A1. The display panel includes a substrate 10, an isolation structure 20, a light-emitting functional layer, and first signal lines 60. The isolation structure 20 is arranged on a side of the substrate 10; the isolation structure 20 encloses to form a plurality of opening structures 21 that are arranged at intervals. The light-emitting functional layer is arranged on the side of the substrate 10 and is positioned at least in the first area A1; the light-emitting functional layer includes a plurality of light-emitting structures 31 respectively provided in the plurality of opening structures 21, and at least one light-emitting structure 31 is provided in each of the opening structures 21. For example, there is one light-emitting structure 31 in one opening structure 21, or there are a plurality of light-emitting structures 31 emitting the same color in one opening structure 21.

The first signal lines 60 are positioned on a side of the isolation structure 20 along a first direction X, and the first signal lines 60 are electrically connected to the isolation structure 20. The first direction X is parallel to a plane of the substrate 10.

In additional to the first area A1, the display panel further has a second area A2. The first area A1 is a display area in the display panel for achieving a display effect, the second area A2 surrounds the periphery of the first area A1 and is mainly used for arranging a driving circuit in the display panel, and the second area A2 is a non-display area. Sizes and shapes of the first area A1 and the second area A2 are not limited in embodiments of the present application. Illustratively, the first area A1 may have a structure of a square and the second area A2 may have a structure of a square ring.

The substrate 10 mainly plays a supporting and bearing role, and other film layers are successively stacked on the substrate 10. The stacked arrangement mentioned herein means that the other film layers are successively arranged along a thickness direction Z of the substrate 10. The substrate 10 may include a structure of multiple film layers, and particular components of the multiple film layers of the substrate 10 are not limited in embodiments of the present application. In addition, the thickness direction Z of the other film layers positioned on a side of the substrate 10 is generally consistent with the thickness direction Z of the substrate 10 itself, and therefore, for the convenience of expression, the thickness direction Z of the substrate 10 or the thickness direction Z of the other film layers mentioned later in the embodiments of the present application are both illustrated in the same direction.

The light-emitting functional layer is positioned on the same side of the substrate 10 as the isolation structure 20. The light-emitting functional layer is positioned in the first area A1 and includes a plurality of light-emitting structures 31 that are main devices for light-emitting display. The light-emitting structures 31 each include, but are not limited to, a red light-emitting structure 31 for emitting red light, a green light-emitting structure 31 for emitting green light, and a blue light-emitting structure 31 for emitting blue light. Each light-emitting structure 31 may include a Hole Inject Layer (HIL), a Hole Transport Layer (HTL), a light-emitting layer, an Electron Inject Layer (EIL), and an Electron Transport Layer (ETL) arranged in a stack.

Optionally, the display panel further includes a first electrode layer 40. The first electrode layer 40 is positioned on a side of the light-emitting functional layer facing away from the substrate 10. Further, the display panel further includes a second electrode layer 50 positioned on a side of the light-emitting functional layer facing the substrate 10. The first electrode layer 40 is provided with a first electrode(s) 41, and the second electrode layer 50 is provided with a second electrode(s) 51. There may be a plurality of second electrodes 51 that are arranged correspondingly to the light-emitting structures 31. The first electrode(s) 41 and the second electrode(s) 51 jointly drive and control whether the light-emitting structures 31 emit light or not. Illustratively, the first electrode(s) 41 are cathode(s) and the second electrode(s) 51 are anode(s).

The isolation structures 20 can enclose to form a plurality of opening structures 21. Illustratively, an orthographic projection of the isolation structures 20 on the substrate 10 is in the form of a net-like structure. The multiple light-emitting structures 31 are respectively provided in the plurality of opening structures 21, namely, orthographic projections of the light-emitting structures 31 on the substrate 10 are arranged correspondingly to orthographic projections of the opening structures 21 on the substrate 10, and the orthographic projections of the light-emitting structures 31 on the substrate 10 are at least partially positioned in the orthographic projections of the opening structures 21 on the substrate 10. Further, during the fabrication of the light-emitting functional layer, a precision metal photomask may be eliminated due to the presence of the isolation structure 20.

Specifically, it is taken as an example that the red light-emitting structure 31 is prepared before the green light-emitting structure 31. Since the precision metal photomask is eliminated, a red light-emitting material corresponding to the red light-emitting structure 31 firstly falls into each of the opening structures 21, and then the red light-emitting material in a part of the opening structures 21 is selectively etched away and the red light-emitting material in the other part of the opening structures 21 remains to form the red light-emitting structure 31. After that, a green light-emitting material corresponding to the green light-emitting structure 31 falls into each of the opening structures 21, and then the green light-emitting material in a part of the opening structure 21 is selectively etched away and the green light-emitting material in the other part of the opening structure 21 remains to form the green light-emitting structure 31.

Similarly, due to the presence of the isolation structure 20, the first electrode layer 40 may also include a plurality of first electrodes 41 provided respectively in the opening structures 21, namely, the plurality of first electrodes 41 may be arranged correspondingly to the plurality of light-emitting structures 31 so as to achieve drive control over the light-emitting structures 31.

Further optionally, the first electrodes 41 may be electrically connected to the isolation structure 20, i.e. the isolation structure 20 may include a conductive material therein, and the first electrodes 41 and the conductive material in the isolation structure 20 can be interconnected. With this design, the power supply signals corresponding to the first electrodes 41 can be transmitted into the first electrodes 41 by means of the isolation structure 20, to meet the requirement for transmitting the power supply signals.

It should be noted that the conductive material provided in the isolation structure 20 for electrical connection with the first electrodes 41 can be provided in a continuous manner, i.e. an effect that the same power supply signals can be transmitted to the respective first electrodes 41 can be achieved by means of the isolation structure 20. Alternatively, the conductive material provided in the isolation structure 20 for electrical connection with the first electrodes 41 may be provided in a discontinuous manner or mutually insulated, i.e. at least some different first electrodes 41 may receive or transmit power supply signals with different voltage levels by means of the isolation structure 20, thereby achieving independent or partitioned control of the light-emitting structures 31, which is not limited in the embodiments of the present application.

The display panel further includes a first signal line(s) 60 for transmitting a particular signal(s). In the related art, there is a need for a partial structure of the first signal line(s) 60 positioned in the second area A2 to be arranged around the periphery of the first area A1 in an annular structure, so that a signal(s) in the first signal line(s) can be transmitted to different positions in the first area A1, and it contributes to a reduction in voltage drop. However, in this design, the first signal line(s) 60 occupies an excessive size at the bezel of the display panel, which is disadvantageous for achieving an effect of a narrow bezel.

However, in the embodiment of the present application, the first signal line(s) 60 are not arranged around the first area A1, but are arranged on a side of the first area A1 along the first direction X and transmit signals to different positions of the first area A1 by means of the isolation structure 20. Specifically, since the isolation structure 20 is distributed at various positions throughout the first area A1, and there is a conductive material provided in the isolation structure 20 for transmitting particular signals.

Therefore, there is no need for the first signal lines 60 to be arranged around the first area A1, as long as the first signal lines 60 are arranged on a side of the isolation structure 20 along the first direction X, and are electrically connected to the isolation structure 20. As such, power supply signals in the first signal lines 60 can be transmitted to different positions in the first area A1 by means of the isolation structure 20, thereby satisfying the need for signal transmission. Furthermore, since the first signal lines 60 are positioned on the side of the isolation structure 20 along the first direction X, rather than in an annular structure, it contributes to reducing the bezel size of the display panel and improve the display effect.

It should be noted that the embodiments of the present application do not limit the specific routing pattern of the first signal lines 60. Furthermore, according to practical situations, the first signal lines 60 may all be positioned on one side of the isolation structure 20 along the first direction X, or a small number of the first signal lines 60 may be positioned on the other side of the isolation structure 20 along a different direction, as long as most of the first signal lines 60 are positioned on the same side of the isolation structure 20.

In some embodiments, as shown in FIG. 1-FIG. 3, the isolation structure 20 includes a first isolation portion 22 and a second isolation portion 23 stacked sequentially in a direction away from the substrate 10, and an orthographic projection of the first isolation portion 22 on the substrate 10 is positioned within an orthographic projection of the second isolation portion 23 on the substrate 10.

Specific sizes and shapes of the first isolation portion 22 and the second isolation portion 23 are not limited in the embodiments of the present application. Illustratively, a longitudinal cross-section of the isolation structure 20 may be T-shaped. This design helps to make it difficult for a light-emitting material and an electrode material to extend along the side wall of the first isolation portion 22 to the side wall of the second isolation portion 23 during the preparation of the light-emitting functional layer and the first electrode layer 40, so that the light-emitting structures 31 and first electrodes 41 in the different opening structures 21 can be prepared and separated from each other, without requiring a precision metal photomask.

Material compositions in the first isolation portion 22 and the second isolation portion 23 are not limited in the embodiments of the present application. Both the first isolation portion 22 and the second isolation portion 23 may include conductive materials, or the first isolation portion 22 includes a conductive material, and the second isolation portion 23 includes an insulating material, as long as the first electrode(s) 41 can achieve signal transmission by means of the isolation structure 20.

Further, at least some of the first signal lines 60 are positioned within the second area A2, alternatively, the first signal lines 60 may be positioned entirely within the second area A2, or the first signal lines 60 may also extend partially into the first area A1. Similarly, the isolation structure 20 may be positioned entirely within the first area A1, or the isolation structure 20 may also extend partially into the second area A2, which is not limited in the embodiments of the present application.

In some embodiments, the display panel further includes a first electrode layer 40 arranged on a side of the light-emitting functional layer away from the substrate 10, and the first electrode layer 40 includes a plurality of first electrodes 41 provided in the plurality of opening structures 21 respectively. The first electrodes 41 are electrically connected to the first signal lines 60 via the isolation structure 20.

In the embodiment of the present application, the first signal line(s) 60 are not directly connected to the first electrode(s) 41, and transmit the power supply signal(s) to the respective first electrodes 41 by means of the isolation structure 20. Specifically, since the isolation structure 20 itself is arranged correspondingly to the respective first electrodes 41 and it is possible to achieve signal transmission between them, it is not necessary to extend the first signal lines 60 correspondingly to positions of the respective first electrodes 41, that is, there is no need for the first signal lines 60 to be arranged around respective first electrodes 41, as long as the first signal lines 60 are arranged on a side of the isolation structure 20 along the first direction X, and are electrically connected to the isolation structure 20. As such, power supply signals in the first signal lines 60 can be transmitted to the respective first electrodes 41 by means of the isolation structure 20, thereby satisfying the need for signal transmission. Furthermore, since the first signal lines 60 are positioned on the side of the isolation structure 20 along the first direction X, rather than in an annular structure, it contributes to reducing the bezel size of the display panel and improving the display effect.

In some embodiments, the first isolation portion 22 includes a conductive material and the first electrodes 41 are electrically connected to the first isolation portion 22.

The first signal lines 60 may transmit power supply signals to the first electrode 41 via the first isolation portion 22. The first electrodes 41 may be in direct contact with the first isolation portion 22, or the first electrodes 41 may be electrically connected to the first isolation portion 22 via another conductive structure, which is not limited in the embodiments of the present application.

In the embodiment of the present application, by providing a conductive material in the first isolation portion 22, the first signal lines 60 can transmit the power supply signals to the first electrodes 41 via the first isolation portion 22, thereby satisfying the need for signal transmission. Further, by setting a path along which the first isolation portion 22 extends in the first area A1, the first isolation portion 22 can extend to the whole range of the first area A1, and it is in turn that the first signal lines 60 are only needed to be arranged on one side of the isolation structure 20 along the first direction X, instead of being arranged around the first area A1, thereby reducing the display panel's bezel size.

A position relationship between the first signal lines 60 and the first isolation portion 22 is not limited in the embodiments of the application. In some embodiments, at least some of the first signal lines 60 are in contact with the first isolation portion 22, i.e. the power supply signals in at least some of the first signal lines 60 may be transmitted directly into the first isolation portion 22. Further, if the isolation structure 20 further includes other conductive structures electrically connected to the first isolation portion 22, the first signal lines 60 may also be in contact with the other conductive structures.

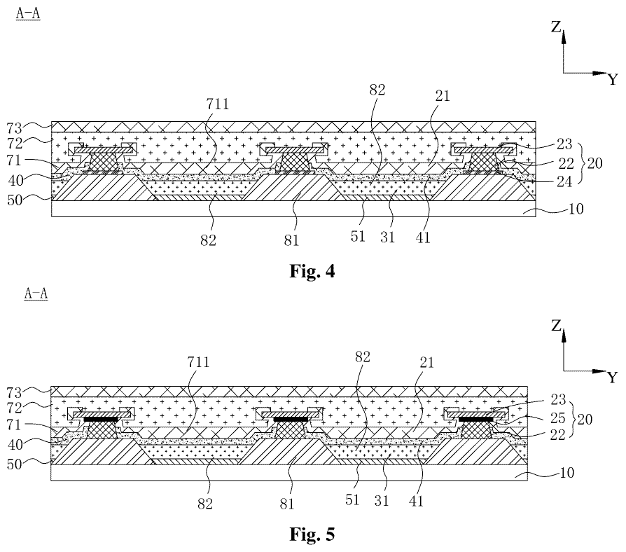

In some embodiments, as shown FIG. 4, the isolation structure 20 further includes a third isolation portion 24 positioned on a side of the first isolation portion 22 facing the substrate 10. The third isolation portion 24 includes a conductive material and is electrically connected to the first isolation portion 22.

The isolation structure 20 includes at least the first isolation portion 22, the second isolation portion 23 and the third isolation portion 24. Sizes and shapes of the first isolation portion 22, the second isolation portion 23 and the third isolation portion 24 are not limited in the embodiments of the present application. Illustratively, the orthographic projection of the first isolation portion 22 on the substrate 10 is positioned within an orthographic projection of the third isolation portion 24 on the substrate 10, i.e. a longitudinal cross-section of the first isolation portion 22, the second isolation portion 23 and the third isolation portion 24 is I-shaped.

Similar to the first isolation portion 22, the third isolation portion 24 also includes a conductive material, and the first electrodes 41 can be in direct contact with the third isolation portion 24 so as to be electrically connected to the first isolation portion 22 via the third isolation portion 24. Optionally, the first electrodes 41 are overlapped with the third isolation portion 24. Further, the first electrodes 41 may be positioned partially on a side of the third isolation portion 24 facing away from the substrate 10. The arrangement of the third isolation portion 24 helps to improve the reliability of the electrical connection between the first electrodes 41 and the isolation structure 20.

In some embodiments, the second isolation portion 23 includes a conductive material.

Similar to the first isolation portion 22, the second isolation portion 23 also includes a conductive material, that is to say, the second isolation portion 23 can also be used for signal transmission. The first isolation portion 22 and the second isolation portion 23 can be arranged in electrical connection with each other, namely, the second isolation portion 23 can also be used for transmitting power supply signals, or alternatively, the first isolation portion 22 and the second isolation portion 23 can be arranged in an insulation arrangement, namely, the second isolation portion 23 cannot be used for transmitting power supply signals, which is not limited in the embodiments of the present application.

Further optionally, the first isolation portion 22 is electrically connected to the second isolation portion 23, and at least portions of the first signal line 60 are in contact with the second isolation portion 23.

In this case, the first isolation portion 22 may be in direct contact with the second isolation portion 23, and thus the same electrical signals are transmitted in the first isolation portion 22 and the second isolation portion 23. At this time, the first signal lines 60 may be in contact with the second separator 23, and the power supply signals in the first signal lines 60 are transmitted into the first isolation portion 22 via the second isolation portion 23, and then transmitted into the first electrodes 41 via the first isolation portion 22, thereby satisfying the need for transmitting the power supply signals.

In some embodiments, as shown in FIG. 5, the isolation structure 20 may further include a first insulation portion 25 arranged between the first isolation portion 22 and the second isolation portion 23.

A size of the first insulation portion 25 with respect to the first isolation portion 22 and the second isolation portion 23 is not limited in the embodiments of the present application. Illustratively, the orthographic projection of the first isolation portion 22 on the substrate 10 is positioned within an orthographic projection of the first insulation portion 25 on the substrate 10, and the orthographic projection of the first insulator 25 on the substrate 10 is positioned within the orthographic projection of the second isolation portion 23 onto the substrate 10. This helps to further reduce the risk that the light-emitting material and the electrode material extend from the side wall of the first isolation portion 22 to the side wall of the second isolation portion 23, and improve the reliability for manufacturing the display panel.

Due to the presence of the first insulation portion 25, the first isolation portion 22 is insulated from the second isolation portion 23, and the power supply signals within the first isolation portion 22 will not be transmitted into the second isolation portion 23. On this basis, the display panel can transmit other different types of signals via the second isolation portion 23, which helps to reduce the number of tracks inside the display panel and to reduce difficulties for track design. Optionally, the second isolation portion 23 may be used for touch signals.

In some embodiments, an etching selectivity ratio of the first isolation portion 22 to the second isolation portion 23 is greater than 1.

An etching selectivity ratio indicates a relative etching rate of one material with respect to another material under the same etching condition. Since the etching selectivity ratio of the first isolation portion 22 to the second isolation portion 23 is greater than 1, under the same etching condition, an etching rate corresponding to the first isolation portion 22 is greater than an etching rate corresponding to the second isolation portion 23.

On this basis, the first isolation portion 22 and the second isolation portion 23 can be prepared and formed in the same etching process, which can not only reduce the preparation process of the display panel and improve the preparation efficiency, but also ensure that, after the preparation, the orthographic projection of the first isolation portion 22 on the substrate 10 can be positioned within the orthographic projection of the second isolation portion 23 on the substrate 10, thereby having an improved practicality.

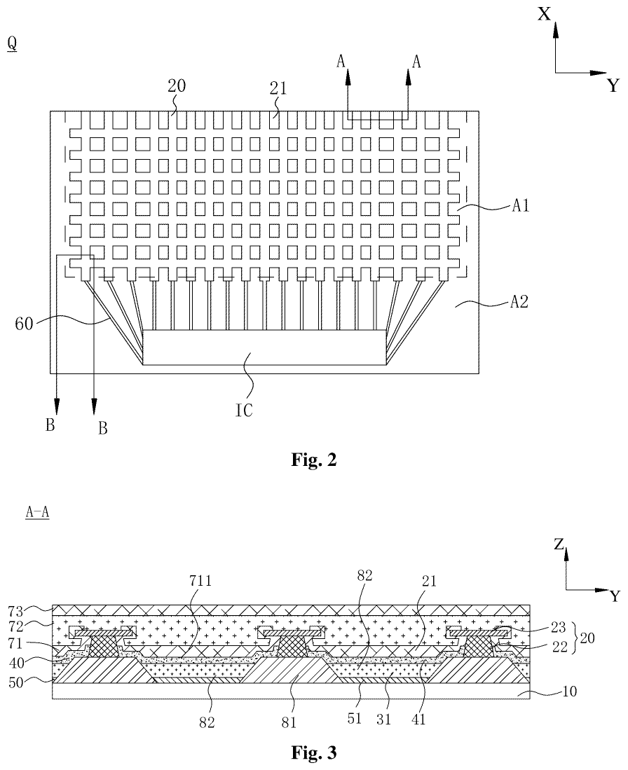

In some embodiments, as shown in FIG. 2 and FIG. 3, the display panel further has a second area A2 surrounding a periphery of the first area A1, the display panel further includes a driving chip Integrated Circuit (IC) arranged in the second area A2 and positioned on the side of the isolation structure 20 along the first direction X, and the first signal lines 60 are electrically connected to the driving chip IC.

The driving chip IC is a driving control element and can control the first electrodes 41. Further, the driving chip IC is positioned within the second area A2 and on the side of the isolation structure 20 along the first direction X. On this basis, in order to achieve the electrical connection between the driving chip IC and the first electrodes 41, the embodiment of the present application adds first signal lines 60 between the driving chip IC and the isolation structure 20. The first signal lines 60 are positioned between the driving chip IC and the isolation structure 20 along the first direction X; the driving chip IC transmits corresponding power supply signals into the first signal lines 60, and then the power supply signals are transmitted into the isolation structure 20 via the first signal lines 60, and finally the isolation structure 20 transmits the power supply signals to the first electrodes 41, so as to achieve driving control over the first electrodes 41.

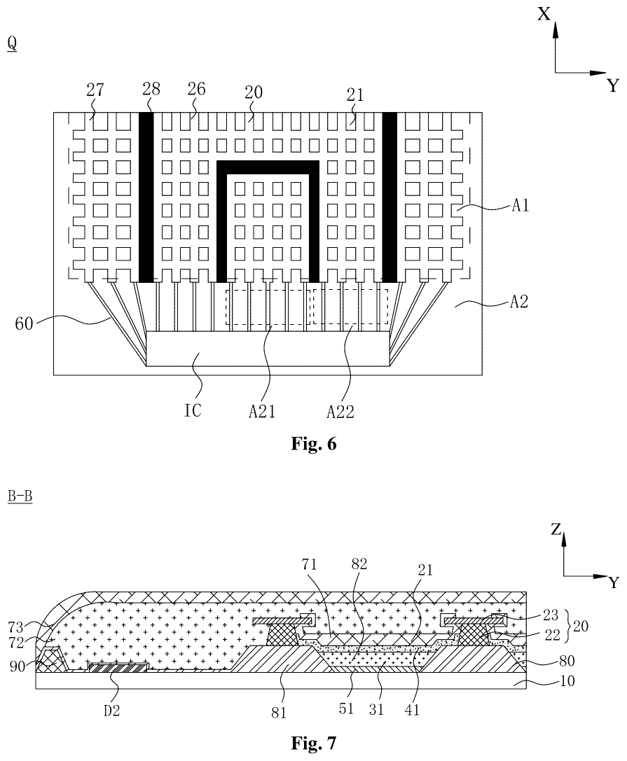

Further, as shown in FIG. 6, in some embodiments, the second area A2 includes a first subarea A21 and a second subarea A22 positioned between the driving chip IC and the isolation structure 20. The first subarea A21 and the second subarea A22 are arranged side by side in a second direction Y, which is set to intersect the first direction X. The first signal lines 60 positioned in the first subarea A21 and the first signal lines 60 positioned in the second subarea A22 are insulated from each other.

The first subarea A21 and the second subarea A22 are both positioned between the driving chip IC and the isolation structure 20. A specific position relationship between the first subarea A21 and the second subarea A22 is not limited in the embodiments of the present application, as long as the first subarea A21 and the second subarea A22 are arranged side by side in the second direction Y Optionally, the first direction X is arranged perpendicularly to the second direction Y.

Both the first subarea A21 and the second subarea A22 have first signal lines 60 provided therein. The first subarea A21 may have only one first signal line 60 provided therein, or alternatively, the first subarea A21 may have a plurality of first signal lines 60 provided therein. Similarly, the second subarea A22 may have only one first signal line 60 provided therein, or alternatively, the second subarea A22 may have a plurality of first signal lines 60 provided therein.

It can be seen from the foregoing that the first signal lines 60 are all electrically connected to the isolation structure 20 so as to be electrically connected to the first electrodes 41 via the isolation structure 20. On this basis, the first signal line(s) 60 positioned in the first subarea A21 and the first signal line(s) 60 positioned in the second subarea A22 are insulated from each other. That is to say, a part of the isolation structure 20 electrically connected to the first signal line(s) 60 positioned in the first subarea A21 and another part of the isolation structure 20 electrically connected to the first signal line(s) 60 positioned in the second subarea A22 insulated from each other, so that the first signal line(s) 60 positioned in the first subarea A21 and the first signal line(s) 60 positioned in the second subarea A22 can respectively control different first electrodes 41, thereby helping to improve the control accuracy.

In some embodiments, as shown in FIG. 6, the isolation structure 20 includes a first isolation structure 26 and a second isolation structure 27 that are mutually insulated. The first isolation structure 26 and the second isolation structure 27 are positioned in different subareas in the first area A1. The first isolation structure 26 and the second isolation structure 27 have different resistances in the same orthographic projection area, and different first signal lines 60 are electrically connected to the first isolation structure 26 and the second isolation structure 27, respectively.

The first isolation structure 26 and the second isolation structure 27 are mutually insulated. Sizes and shapes of the first isolation structure 26 and the second isolation structure 27 are not limited in the embodiments of the present application. Illustratively, the first isolation structure 26 may be in a shape of a strip or mesh or the like, so as the second isolation structure.

A resistance corresponding to the first isolation structure 26 is different from that corresponding to the second isolation structure 27 due to factors such as differences in the extension length and shape between the first isolation structure 26 and the second isolation structure 27. On this basis, if power supply signals of the same voltage magnitude are input into the first isolation structure 26 and the second isolation structure 27, different first electrodes 41 corresponding to the first isolation structure 26 and the second isolation structure 27 will receive power supply signals of different magnitudes. As a result, problems such as uneven display of the display panel and the like are liable to occur, which are harmful to the display effect.

On this basis, in the embodiments of the present application, different first signal lines 60 are electrically connected to the first isolation structure 26 and the second isolation structure 27 respectively, and the driving chip IC can control the different first signal lines 60 to input different voltages respectively to the first isolation structure 26 and the second isolation structure 27 according to the resistances of the first isolation structure 26 and the second isolation structure 27, so as to ensure different first electrodes 41 corresponding to the first isolation structure 26 and the second isolation structure 27 can receive accurate voltage signals, thereby improving the control accuracy of the first electrodes 41 and improving the display uniformity.

It should be noted that a relationship between resistance values of the first isolation structure 26 and the second isolation structure 27 is not limited in the embodiments of the present application. Optionally, an orthographic projection area of the first isolation structure 26 on the substrate 10 and an orthographic projection area of the second isolation structure 27 on the substrate 10 are different, and thus there is a different between their resistance values. Specifically, in general, the larger an orthographic projection area on the substrate 10 is, the larger a corresponding resistance value thereof, the smaller an orthographic projection area on the substrate 10, the smaller a corresponding resistance value thereof.

In other embodiments, the first isolation structure 26 and the second isolation structure 27 have different cross-sectional dimensions, and thus have different resistance values. Specifically, in general, the larger a cross-sectional dimension is, the smaller a corresponding resistance value, and the smaller a cross-sectional dimension, the larger a corresponding resistance value.

Furthermore, a manner of insulation between the first isolation structure 26 and the second isolation structure 27 is not limited in the embodiments of the present application. Optionally, the first isolation structure 26 is spaced apart from the second isolation structure 27. Further optionally, the isolation structure 20 also includes an insulation structure 28 between the first isolation structure 26 and the second isolation structure 27.

In some embodiments, as shown in FIG. 3, the display panel further includes a first encapsulation layer 71 arranged on a side of the first electrode layer 40 facing away from the substrate 10. The first encapsulation layer 71 includes a plurality of first encapsulation portions 711 provided in the opening structures 21 respectively.

The first encapsulation layer 71 is positioned on the side of the first electrode layer 40 facing away from the substrate 10, i.e. on a side of the light-emitting structures 31 where light emits from. The first encapsulation layer 71 may encapsulate and protect the light-emitting structures 31. Due to the presence of the isolation structure 20, the prepared first encapsulation layer 71 may include a plurality of first encapsulation portions 711 corresponding to the light-emitting structures 31 and positioned in the opening structures 21, and each first encapsulation portion 711 may encapsulate each light-emitting structure 31 independently, thereby improving the encapsulation and protection effect on the light-emitting structures 31.

The material composition of the first encapsulation layer 71 is not limited in the embodiments of the present application. Illustratively, the first encapsulation layer 71 includes an inorganic material.

In some embodiments, the display panel further includes a second encapsulation layer 72 on a side of the first encapsulation layer 71 facing away from the substrate 10, and a third encapsulation layer 73 on a side of the second encapsulation layer 72 facing away from the substrate 10.

The first encapsulation layer 71, the second encapsulation layer 72 and the third encapsulation layer 73 may jointly form a thin film encapsulation structure, thereby further reducing the risk of intrusion of water, oxygen and the like into the light-emitting structures 31 and improving the reliability of the display panel. The material compositions of the second encapsulation layer 72 and the third encapsulation layer 73 are not limited in the embodiments of the present application. Optionally, both the first encapsulation layer 71 and the third encapsulation layer 73 include an inorganic material, and the second encapsulation layer 72 includes an organic material, so that the first encapsulation layer 71 and the second encapsulation layer 72 can limit the position of the second encapsulation layer 72 to a certain extent, so as to improve the structural reliability.

Unlike the first encapsulation layer 71, the second encapsulation layer 72 and the third encapsulation layer 73 may be of a monolithic structure, i.e. both an orthographic projection of the second encapsulation layer 72 on the substrate 10 and an orthographic projection of the second encapsulation layer 72 on the substrate 10 may cover orthographic projections of the plurality of light-emitting structures 31 on the substrate 10.

In some embodiments, as shown in FIG. 2, FIG. 3, and FIG. 7, the display panel further includes a blocking portion 90 arranged in the second area A2. An orthographic projection of a structure of the blocking portion 90 positioned on both sides of the first area A1 along a second direction Y on the substrate 10 does not overlap with orthographic projections of the first signal lines 60 on the substrate 10. The first direction X intersects the second direction Y.

The blocking portion 90 is positioned in the second area A2, and the blocking portion 90 is generally positioned on an edge position of the display panel. It can be seen from the above contents that the second encapsulation layer 72 includes an organic material, and the organic material included in the second encapsulation layer 72 generally has a certain fluidity, and thus in order to reduce the risk of the organic material in the second encapsulation layer 72 overflowing, the blocking portion 90 is generally arranged on the edge position of the display panel, and the presence of the blocking portion 90 can reduce the risk of overflowing and improve the reliability of the display panel.

For example, the second area A2 includes a left bezel, a right bezel and a bottom bezel. The first signal lines 60 are positioned on the bottom bezel and are not arranged on the left bezel and the right bezel, and then the orthographic projection of the blocking portion 90 positioned on the left bezel and the right bezel on the substrate 10 does not overlap with the orthographic projections of the first signal lines 60 on the substrate 10.

Further, since the first signal lines 60 are only positioned on one side of the isolation structure 20 and along the first direction X, instead of being arranged around the periphery of the isolation structure 20, there may be no first signal line 60 at some positions in the second area A2, for example, the local portions of the second area A2 positioned on two sides of the first area A1 along the second direction Y On this basis, the orthographic projection on the substrate 10 of the structure of the blocking portion 90 positioned on two sides of the first area A1 along the second direction Y can be offset from the orthographic projections of the first signal lines 60 on the substrate 10, namely, the first signal lines 60 will not affect a layout design of the blocking portion 90, which helps to reduce the risk of physical interference between them.

In some embodiments, the orthographic projection of the first encapsulation layer 71 on the substrate 10 does not overlap with the orthographic projection of the blocking portion 90 on the substrate 10.

Due to the presence of the isolation structure 20, the first encapsulation portions 711 in the first encapsulation layer 71 will fall into the opening structures 21 and are arranged correspondingly to the light-emitting structure 31. Thus, the first encapsulation layer 71 will be mostly positioned in the first area A1, and the first encapsulation layer 71 will end up near the intersection of the first area A1 and the second area A2. The second encapsulation layer 72 typically will cover more than the first area A1 and extend into the second area A2, so that the first encapsulation layer 71 has less influence on the limiting of the second encapsulation layer 72 in the second area A2.

On this basis, the second encapsulation layer 72 needs to be limited in position by means of other structures in the display panel except the first encapsulation layer 71. Since the blocking portion 90 and the first encapsulation layer 71 are not arranged on the substrate 10 without overlapping with each other, the presence of the blocking portion 90 can have a limiting effect on the second encapsulation layer 72, thereby reducing the risk of overflowing for the second encapsulation layer 72.

In some embodiments, as shown in FIG. 7, the third encapsulation layer 73 is positioned on a side of the blocking portion 90 facing away from the substrate 10 and covers at least a partial structure of the blocking portion 90.

Unlike the first encapsulation layer 71, the third encapsulation layer 73 may be in a monolithic structure, and the third encapsulation layer 73 may be partially positioned within the second area A2. On this basis, in the embodiment of the present application, the third encapsulation layer 73 covers at least a partial structure of the blocking portion 90, so that the third encapsulation layer 73 can cooperate with the blocking portion 90 to play the role of limiting the second encapsulation layer 72.

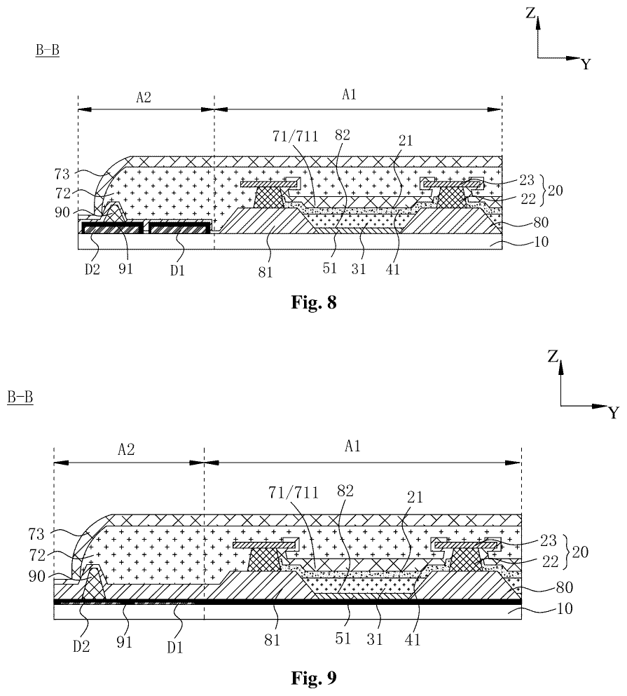

In some embodiments, as shown in FIG. 8, the display panel further includes a gate driving circuit positioned in the second area, and at least a part of the blocking portion 90 is positioned on a side of the gate driving circuit facing away from the substrate 10. The gate driving circuit may include a light-emitting control circuit D2.

A variety of other film layer structures are contained in the display panel. Some of the film layers have a certain fluidity due to factors such as material compositions and the like. In order to achieve an effective cut-off for such film layer structures, the display panel in the embodiments of the present application is further provided with a blocking portion 90 positioned in the second area A2, which mainly serves to block and reduce the probability of some of the film layers flowing to a side of the blocking portion 90 facing away from the first area A1, so as to improve the reliability of the internal structure of the display panel.

In general, a film layer structure having fluidity itself has a certain thickness dimension, and the thickness of such a film layer structure gradually decreases as it approaches an edge position of a display panel. On this basis, if the blocking portion 90 is provided at a position closer to the first area A1, it is necessary to provide a larger dimension of the blocking portion 90 in the thickness direction Z to satisfy the requirement for blocking, but this is not conducive to the overall thickness design of the display panel. In view of this, the blocking portion 90 is generally positioned on a remote position from the first area A1, and further, in the related art, the blocking portion 90 may be positioned on a side of the light-emitting control circuit D2 facing away from the first area A1.

The gate driving circuit is positioned in the second area A2, and the blocking portion 90 is positioned on the side of the gate driving circuit facing away from the first area A1, namely, the blocking portion 90 is spaced apart from the gate driving circuit in a direction parallel to the plane of the substrate 10.

However, in the embodiments of the present application, since the isolation structure 20 encloses to form the plurality of opening structures 21, and at least some of the opening structures 21 can be used for accommodating a film layer structure having fluidity, the presence of the isolation structure 20 can reduce thickness dimensions of some of the film layers in the second area A2. On this basis, the embodiments of the present application can appropriately move the blocking portion 90 in the direction towards the first area A1, so that at least a part of the blocking portion 90 is positioned on a side of the gate driving circuit facing away from the substrate 10, without excessively increasing the height of the blocking portion 90, which helps to alleviate the problem that the bezel size of the display panel is too large due to a too large distance between the blocking portion 90 and the first area A1, helping to reduce the bezel size of the display panel and improve the display effect.

Further optionally, at least a part of the blocking portion 90 may be positioned on a side of the light-emitting control circuit D2 facing away from the substrate 10.

It should be noted that the blocking portion 90 can be positioned entirely on the side of the light-emitting control circuit D2 facing away from the substrate 10; alternatively, a part of the blocking portion 90 can be positioned on the side of the light-emitting control circuit D2 facing away from the substrate 10, and another part of the blocking portion 90 can be positioned on a side of the light-emitting control circuit D2 close to the first area A1; alternatively, a part of the blocking portion 90 can be positioned on the side of the light-emitting control circuit D2 facing away from the substrate 10, and another part of the blocking portion 90 can be positioned on a side of the light-emitting control circuit D2 far away from the first area A1, which is not limited in the embodiments of the present application. Since the light-emitting control circuit D2 itself has a certain thickness dimension, the presence of the light-emitting control circuit D2 helps to reduce the height dimension of at least a partial structure of the blocking portion 90 positioned on the side of the light-emitting control circuit D2 facing away from the substrate 10, thereby reducing the material cost corresponding to the blocking portion 90, and providing a strong practicality.

In some embodiments, the display panel further includes a second encapsulation layer 72 arranged on a side of the light-emitting functional layer facing away from the substrate 10, and the second encapsulation layer 72 includes an organic material. Further, the second encapsulation layer 72 may be partially positioned within the opening structures 21.

The second encapsulation layer 72 is positioned on the side of the light-emitting functional layer facing away from the substrate 10, namely, on the light-emitting surface side of the light-emitting structure 31. The second encapsulation layer 72 is partially positioned in the first area A1 and partially positioned in the second area A2. The second encapsulation layer 72 is mainly used for encapsulating and protecting the light-emitting structures 31, so as to reduce the risk of water and oxygen intrusion into the light-emitting structures 31, and improving the light-emitting reliability of the display panel.

The second encapsulation layer 72 includes an organic material, and has a certain fluidity; however, since the second encapsulation layer 72 can be partially positioned in the opening structures 21, the opening structures 21 can play a certain role of accommodating overflow for the second encapsulation layer 72, so that the thickness dimension of the second encapsulation layer 72 at the second area A2 is reduced, and in turn the distance between the blocking portion 90 and the first area A1 can be reduced to enable at least a part of the blocking portion 90 to be positioned on the side of the light-emitting control circuit D2 facing away from the substrate 10, which helps to achieve a narrow-bezel display effect of the display panel.

In some embodiments, as shown in FIG. 8, the display panel further includes a first encapsulation layer 71 arranged between the second encapsulation layer 72 and the light-emitting functional layer, and a third encapsulation layer 73 positioned on a side of the second encapsulation layer 72 facing away from the substrate 10. The first encapsulation layer 71 and the third encapsulation layer 73 includes inorganic materials.

The first encapsulation layer 71 and the third encapsulation layer 73 are respectively positioned on two sides of the second encapsulation layer 72 in the thickness direction Z, and the first encapsulation layer 71, the second encapsulation layer 72 and the third encapsulation layer 73 jointly form a thin film encapsulation structure, thereby improving the encapsulation and protection effect on the light-emitting functional layer. The first encapsulation layer 71 and the third encapsulation layer 73 both include inorganic materials, and the first encapsulation layer 71 and the third encapsulation layer 73 can play a role of limiting and blocking the second encapsulation layer 72.

Further optionally, the first encapsulation layer 71 includes a plurality of first encapsulation portions 711 provided in the opening structures 21 respectively. The first encapsulation portions 711 and the blocking portion 90 are arranged at intervals in a direction parallel to the plane of the substrate 10.

Due to the presence of the isolation structure 20, the encapsulation material used to form the first encapsulation portion 711 may also fall into the opening structures 21, thereby forming a plurality of first encapsulation portions 711 arranged correspondingly to the opening structures 21. Different first encapsulation portions 711 are arranged at intervals from each other.

In the embodiments of the present application, due to the presence of the blocking portion 90, the blocking portion 90 can block overflow for the second encapsulation layer 72, thereby reducing the risk of the second encapsulation layer 72 extending to the side of the blocking portion 90 facing away from the first area A1, and improving the encapsulation reliability of the display panel.

In some embodiments, a part of the third encapsulation layer 73 is positioned on a side of the blocking portion 90 facing away from the substrate 10, that is, the third encapsulation layer 73 may extend from the first area A1 into the second area A2 and cover at least a partial structure of the blocking portion 90.

Under this design, the blocking portion 90 may cooperate with the third encapsulation layer 73 so as to jointly play a role of limiting and blocking for the second encapsulation layer 72, further reducing the risk of the second encapsulation layer 72 extending to the side of the blocking portion 90 facing away from the first area A1, and improving the encapsulation reliability of the display panel.

In some embodiments, as shown in FIG. 8, the gate driving circuit further includes a scanning driving circuit D1 positioned between the light-emitting control circuit D2 and the first area A1, the blocking portion 90 is positioned on a side of the scanning driving circuit D1 facing away from the first area A1, or the blocking portion 90 is positioned on a side of the scanning driving circuit D1 facing away from the substrate 10.

The scanning driving circuit D1 and the light-emitting control circuit D2 may both include multiple stages of shift registers cascaded with each other, which may sequentially output conduction levels so as to sequentially scan each row of pixel circuits positioned in the first area A1 to satisfy the display requirement.

The scanning driving circuit D1 and the light-emitting control circuit D2 are both positioned in the second area A2, and the scanning driving circuit D1 is positioned on a side of the light-emitting control circuit D2 close to the first area A1. The distance between the scanning driving circuit D1 and the first area A1 is relatively short. On this basis, in order to ensure the blocking overflow effect of the blocking portion 90 on the first encapsulation layer 71, the embodiments of the present application arrange the blocking portion 90 on a side of the scanning driving circuit D1 facing away from the first area A1, namely, the distance between the blocking portion 90 and the first area A1 is greater than the distance between the scanning driving circuit D1 and the first area A1. This ensures a certain distance between the blocking portion 90 and the first area A1, thereby increasing the effect for blocking overflowing of the blocking portion 90 on the first encapsulation layer 71 without increasing the height dimension of the blocking portion 90.

Alternatively, in the case where the opening structures 21 can accommodate more organic materials in the first encapsulation layer 71, the blocking portion 90 can also be positioned on the side of the scanning driving circuit D1 facing away from the substrate 10, so as to further narrow the bezel of the display panel and improve the display effect.

In some embodiments, an orthographic projection of the blocking portion 90 on the substrate at least partially overlaps with an orthographic projection of the light-emitting control circuit D2 on the substrate; or an orthographic projection of the blocking portion 90 on the substrate at least partially is offset from and adjacent to an orthographic projection of the light-emitting control circuit D2 on the substrate.

In some embodiments, as shown in FIG. 8, the display panel further includes a second insulation portion 91 arranged between the light-emitting control circuit D2 and at least a part of the blocking portion 90.

The second insulation portion 91 may cover at least a partial structure of the light-emitting control circuit D2, for example, an orthographic projection of the second insulation portion 91 on the substrate covers an orthographic projection of the light-emitting control circuit D2 on the substrate, so that after the light-emitting control circuit D2 is prepared, the second insulation portion 91 may play a role of isolating the light-emitting control circuit D2 from the air, and in a subsequent preparation process of a metal layer and the like. The second insulation portion 91 may also play a role of protecting the light-emitting control circuit D2, reducing the risk of over-etching of the light-emitting control circuit D2 and improving the reliability.

In addition, the second insulation portion 91 may insulate and separate the blocking portion 90 from the light-emitting control circuit D2, thereby improving the operational reliability of the light-emitting control circuit D2. It can be seen from the foregoing that the blocking portion 90 can be positioned entirely on the side of the light-emitting control circuit D2 facing away from the substrate 10, or the blocking portion 90 can also be positioned partially on the side of the light-emitting control circuit D2 facing away from the substrate 10 and partially on the side of the light-emitting control circuit D2 facing away from the first area A1. In view of this, the second insulation portion 91 may be positioned entirely on the side of the light-emitting control circuit D2 facing away from the substrate 10, or the second insulation portion 91 may be positioned partially on the side of the light-emitting control circuit D2 facing away from the substrate 10 and partially on the side of the light-emitting control circuit D2 facing away from the first area A1.

When the blocking portion 90 is positioned on the side of the light-emitting control circuit D2 facing away from the substrate 10, the first insulation portion 90 can increase the spacing between the blocking portion 90 and the substrate 10, thereby reducing the required height dimension of the blocking portion 90 and the corresponding material cost, and providing a strong practicality.

In some alternative embodiments, the orthographic projection of the blocking portion 90 on the substrate 10 is positioned within the orthographic projection of the second insulation portion 91 on the substrate 10. As such, the insulating effect of the second insulation portion 91 with respect to the blocking portion 90 and the light-emitting control circuit D2 can be further improved, thereby improving the reliability. Furthermore, due to the presence of the second insulation portion 91, the distance between the blocking portion 90 and the substrate 10 can be increased, so that the height dimension of the blocking portion 90 can be reduced and the material cost corresponding to the blocking portion 90 can be reduced.

Further optionally, the orthographic projection of the blocking portion 90 on the substrate 10 is positioned within the orthographic projection of the lighting control circuit D2 on the substrate 10.

In some embodiments, as shown in FIG. 9, the second insulation portion 91 extends from the first area A1 into the second area A2, and an orthographic projection of the second insulation portion 91 on the substrate 10 covers an orthographic projection of the light-emitting control circuit D2 on the substrate. That is, a partial structure of the second insulation portion 91 positioned in the first area A1 is integrated with a partial structure of the second insulation portion 91 positioned in the second area A2.

In the implementation of the present application, by extending the second insulation portion 91 from the first area A1 to the second area A2, the first insulation portion can not only play the role of insulating and separating different conductive structures in the first area A1, but also play the role of covering and protecting the light-emitting control circuit D2 in the second area, thereby improving the reliability of the display panel. Further optionally, the second insulation portion 91 may be reused as a planarization layer, and the planarization layer may provide a flat surface so as to reduce the difficulty of subsequent preparation of the display panel, and may improve the preparation accuracy of the display panel, thereby providing a strong practicality.

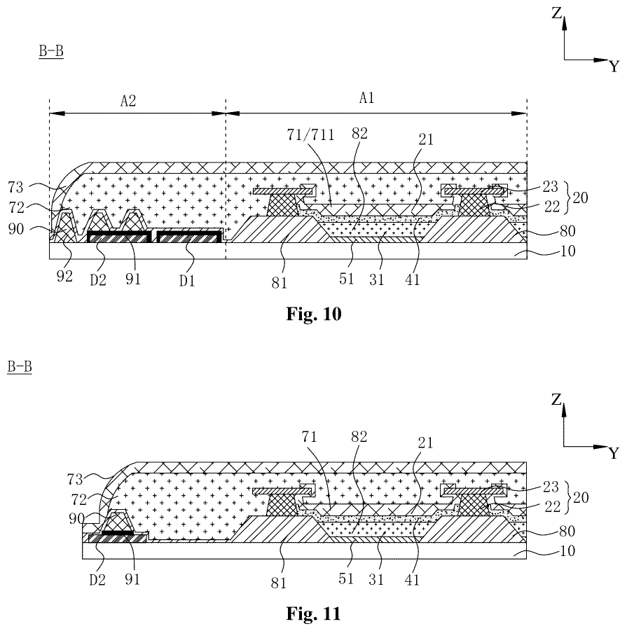

In some embodiments, as shown in FIG. 10, the blocking portion 90 includes a plurality of blocking posts 92 arranged at intervals, and at least some of the blocking posts are positioned on the side of the light-emitting control circuit D2 facing away from the substrate 10.

It can be seen from the foregoing that due to the presence of the isolation structure 20, the distance between the blocking portion 90 and the first area A1 can be reduced appropriately, so that the blocking portion 90 is at least partially positioned on the side of the light-emitting control circuit D2 facing away from the substrate 10. On this basis, on the premise of meeting the requirement of the narrow bezel of the display panel, the blocking portion 90 can be provided with the plurality of blocking posts 92 arranged at intervals, and each blocking post 92 can play the role of blocking overflow for the first encapsulation layer 71, thereby further reducing the trend of the first encapsulation layer 71 extending to the side of the blocking portion 90 facing away from the substrate 10, and improving the encapsulation reliability.

It should be noted that the position relationship between each blocking post 92 and the light-emitting control circuit D2 is not limited in the embodiments of the present application. Illustratively, at least some of the blocking posts 92 are positioned on the side of the light-emitting control circuit D2 facing away from the substrate 10, or some of the blocking posts 92 may also be positioned on the side of the light-emitting control circuit D2 facing away from the first area A1, or some of the blocking post 92 may also be positioned on the side of the light-emitting control circuit D2 close to the first area A1.

In some optional embodiments, each blocking post 92 is positioned on the side of the light-emitting control circuit D2 facing away from the substrate 10, which helps to increase the distance between the blocking post 92 and the substrate 10 in the thickness direction Z, so as to reduce the overall height of the blocking portion 90, thereby reducing the material cost corresponding to the blocking post 92, and providing a strong practicality. Of course, in some other embodiments, it is also possible that only some of the blocking posts 92 are positioned on the side of the lighting control circuit D2 facing away from the substrate 10.

In addition, a number of blocking posts 92 is not limited in the embodiments of the present application. Optionally, the number of the blocking posts 92 is greater than 2. Illustratively, the number of the blocking posts 92 is 3, 4, or 5, etc.

In some embodiments, as shown in FIG. 7, the display panel further includes a light-emitting control circuit D2 positioned in the second area A2; the light-emitting control circuit D2 and the blocking portion 90 are both positioned on the substrate 10; and the light-emitting control circuit D2 and the blocking portion 90 are arranged adjacent to each other, namely, there is no first signal line 60 between the light-emitting control circuit D2 and the blocking portion 90.

Alternatively, in some embodiments, as shown in FIG. 11, the display panel further comprises a lighting control circuit D2 positioned in the second area A2, and the blocking portion 90 is positioned at least partially on the side of the lighting control circuit D2 facing away from the substrate 10. For example, the blocking portion 90 is entirely positioned on the side of the light-emitting control circuit D2 facing away from the substrate 10, or a part of the blocking portion 90 is positioned on the side of the light-emitting control circuit D2 facing away from the substrate 10 and another part of the blocking portion 90 is positioned on the substrate 10. There may be a plurality of blocking portions 90, and the blocking portion 90 closest to the first area A1 is positioned at least partially on the side of the light-emitting control circuit D2 facing away from the substrate 10.

The light-emitting control circuit D2 is positioned within the second area A2, and the light-emitting control circuit D2 may include multiple stages of shift registers cascaded with each other, which may sequentially output conduction levels so as to sequentially scan each row of pixel circuits positioned in the first area A1 to satisfy the display requirement.

In the related art, when the fluidity of the second encapsulation layer 72 is taken into considered, there is generally a need of a relatively large distance between the blocking portion 90 and the first area A1, to enable the blocking portion 90 with a specific height dimension to effectively block the second encapsulation layer 72, and therefore the blocking portion 90 is generally positioned on the side of the scanning driving circuit D1 facing away from the first area A1, which would also affect the bezel size of the display panel, and is not conducive to the display effect.

However, in the embodiments of the present application, due to the presence of the isolation structure 20, a part of the second encapsulation layer 72 will fall into the opening structures 21, and therefore the opening structures 21 can play a certain role of reducing overflowing of the second encapsulation layer 72. On this basis, even if the distance between the blocking portion 90 and the first area A1 in the first direction X is reduced, the blocking portion 90 can still effectively block the second encapsulation layer 72, reducing the risk of overflowing. Therefore, in the embodiments of the present application, the blocking portion 90 is provided at least partially on the side of the light-emitting control circuit D2 facing away from the substrate 10.

Under this design, the blocking portion 90 can effectively block the second encapsulation layer 72 to reduce the risk of overflowing of the second encapsulation layer 72 and improve the encapsulation reliability. This also helps to reduce the distance between the blocking portion 90 and the first area A1, thereby reducing the effect of the blocking portion 90 on the bezel size and further improving the narrow bezel effect.

In some embodiments, the display panel further includes a second insulation portion 91 positioned between the blocking portion 90 and the light-emitting control circuit D2. The second insulation portion 91 may cover at least a partial structure of the light-emitting control circuit D2, so that after the light-emitting control circuit D2 is prepared, the second insulation portion 91 may play a role of isolating the light-emitting control circuit D2 from the air and may also play a role of protecting the light-emitting control circuit D2 in a subsequent preparation process of a metal layer and the like, reducing the risk of over-etching of the light-emitting control circuit D2 and improving the reliability.

Further, in the implementation of the present application, the second insulation portion 91 may insulate the blocking portion 90 from the light-emitting control circuit D2, thereby improving the operational reliability of the light-emitting control circuit D2. The second insulation portion 91 may be positioned entirely on the side of the light-emitting control circuit D2 facing away from the substrate 10, or the second insulation portion 91 may be positioned partially on the side of the light-emitting control circuit D2 facing away from the first area A1.

In addition, when the blocking portion 90 is positioned on the side of the light-emitting control circuit D2 facing away from the substrate 10, the second insulation portion 91 may increase the distance between the blocking portion 90 and the substrate 10, thereby reducing the required height dimension of the blocking portion 90 and the corresponding material cost, and providing a strong applicability.

In some embodiments, the display panel further includes a pixel definition layer 80 arranged on a side of the isolation structure 20 facing the substrate 10. The pixel definition layer 80 includes a pixel defining portion 81 and pixel openings 82 defined by the pixel defining portion 81, and at least a part of each light-emitting structure 31 is positioned in a corresponding pixel opening 82.

The pixel definition layer 80 includes the pixel defining portion 81 and the pixel openings 82, and the pixel openings 82 are provided correspondingly to the opening structures 21. Illustratively, orthographic projections of the pixel openings 82 on the substrate 10 may be positioned within orthographic projections of the opening structures 21 on the substrate 10, and partial structures of the light-emitting structures 31 and the first electrodes 41 may be positioned within the pixel openings 82.

In some embodiments, as shown in FIG. 10, the display panel may further include a pixel definition layer 80. The isolation structures 20 is arranged on a side of the pixel definition layer 80 facing away from the substrate 10 or the isolation structure 20 is arranged in holes in the pixel definition layer 80. The holes may be through holes or blind holes of the pixel definition layer 80. The pixel definition layer 80 includes a pixel defining portion 81 and pixel openings 82 defined by the pixel defining portion 81, and at least a part of each light-emitting structure 31 is positioned in a corresponding pixel opening 82.

The pixel definition layer 80 includes the pixel defining portion 81 and the pixel openings 82, and the pixel openings 82 are provided correspondingly to the opening structures 21. Illustratively, orthographic projections of the pixel openings 82 on the substrate 10 may be positioned within orthographic projections of the opening structures 21 on the substrate 10, and partial structures of the light-emitting structures 31 and the first electrodes 41 may be positioned within the pixel openings 82.

In some embodiments, the pixel definition layer 80 is partially positioned on a side of the blocking portion 90 facing away from the substrate 10.

It can be seen from the foregoing that due to the presence of the isolation structure 20, the first encapsulation layer 71 will end up near the intersection of the first area A1 and the second area A2, and therefore the first encapsulation layer 71 cannot effectively block the second encapsulation layer 72 in the second area A2. On this basis, the pixel definition layer 80 partially covers the blocking portion 90, namely, the pixel definition portion 81 can play the role of blocking and limiting the second encapsulation layer 72 in the second area A2, ensuring the reliability of the internal structure of the display panel.

In some embodiments, the pixel definition layer 80 extends from the first area A1 into the second area A2, i.e. a partial structure of the pixel definition layer 80 positioned in the first area A1 is integrated with a partial structure of the structure of the pixel definition layer 80 positioned in the second area A2.

In some embodiments, an orthographic projection of the light-emitting control circuit D2 on the substrate 10 is positioned within an orthographic projection of the pixel definition layer 80 on the substrate 10, and/or an orthographic projection of the blocking portion 90 on the substrate 10 is positioned within an orthographic projection of an outer edge of the pixel definition layer 80 on the substrate 10.

In the related art, a partial structure of the pixel definition layer 80 positioned in the first area A1 and a partial structure of the pixel definition layer 80 positioned in the second area A2 are in a state of being disconnected from each other. However, in the embodiments of the present application, the pixel definition layer 80 is arranged to extend from the first area A1 to the second area A2, namely, the pixel definition layer 80 may be a monolithic structure and is positioned both in the first area A1 and the second area A2, and this design enables the pixel definition layer 80 to better cover the conductor structure below, which includes for example the light-emitting control circuit D2, so as to improve the preparation reliability of the display panel.

Further, the pixel definition layer 80 includes an inorganic material.

In comparison with an organic material, the intrinsic property of the inorganic material can play a certain role in blocking the liquidity of the first encapsulation layer 71, and therefore, by arranging the pixel definition layer 80 to include the inorganic material, the pixel definition layer 80 can play a role of alleviating overflowing of the first encapsulation layer 71, and it thereby helps to arrange the blocking portion 90 closer to the first area A1, thereby improving the narrow bezel effect of the display panel. Illustratively, pixel definition layer 80 may comprise a silicon nitride material.

In a second aspect, as shown in FIG. 8, an embodiment of the present application provides a display panel having a first area A1 and a second area A2 surrounding a periphery of the first area A1. The display panel includes a substrate 10, an isolation structure 20, a light-emitting functional layer, a gate driving circuit and a blocking portion 90. The isolation structure 20 is arranged on a side of the substrate 10 and encloses to form a plurality of opening structures 21; the light-emitting functional layer is arranged on the side of the substrate 10 and positioned in the first area A1, the light-emitting functional layer includes a plurality of light-emitting structures 31 respectively provided in the plurality of opening structures 21 and at least one light-emitting structure 31 is provided in each of the opening structures 21. For example, there is one light-emitting structure 31 in one opening structure 21, or there are multiple light-emitting structures 31 emitting the same color in one opening structure 21.

The gate driving circuit is positioned in the second area A2; and the blocking portion 90 is arranged in the second area A2, and at least a part of the blocking portion 90 is positioned on a side of the gate driving circuit facing away from the substrate 10. The gate driving circuit may include a light-emitting control circuit D2. An orthographic projection of at least a part of the blocking portion 90 on the substrate 10 overlaps with an orthographic projection of the gate driving circuit on the substrate 10.

The display panel has at least two areas including the first area A1 and the second area A2. The first area A1 is a display area in the display panel for achieving a display effect; the second area A2 surrounds the periphery of the first area A1 and is mainly used for arranging a driving circuit in the display panel, and the second area A2 is a non-display area. Sizes and shapes of the first area A1 and the second area A2 are not limited in embodiments of the present application. Illustratively, the first area A1 may have a structure of a square and the second area A2 may have a structure of a square ring.

The substrate 10 mainly plays a supporting and bearing role, and other film layers are successively stacked on the substrate 10. The stacked arrangement mentioned herein means that the other film layers are successively arranged along a thickness direction Z of the substrate 10. The substrate 10 may include a structure of multiple film layers, and particular components of the multiple film layers of the substrate 10 are not limited in embodiments of the present application. In addition, the thickness direction Z of the other film layers positioned on a side of the substrate 10 is generally consistent with the thickness direction Z of the substrate 10 itself, and therefore, for the convenience of expression, the thickness direction Z of the substrate 10 or the thickness direction Z of the other film layers mentioned later in the embodiments of the present application are both illustrated in the same direction.

The light-emitting functional layer is positioned on the same side of the substrate 10 as the isolation structure 20. The light-emitting functional layer is positioned in the first area A1 and includes a plurality of light-emitting structures 31 that are main devices for light-emitting display. The light-emitting structures 31 include, but are not limited to, a red light-emitting structure 31 for emitting red light, a green light-emitting structure 31 for emitting green light, and a blue light-emitting structure 31 for emitting blue light. Each light-emitting structure 31 may include a Hole Inject Layer (HIL), a Hole Transport Layer (HTL), a light-emitting layer, an Electron Inject Layer (EIL), and an Electron Transport Layer (ETL) arranged in a stack.

Optionally, the display panel may further comprise a first electrode layer 40 on the side of the light-emitting functional layer facing away from the substrate 10. Furthermore, the display panel further comprises a second electrode layer 50 positioned on the side of the light-emitting functional layer facing the substrate 10, wherein the first electrode layer 40 is provided with a first electrode 41, the second electrode layer 50 is provided with multiple second electrodes 51, the multiple second electrodes 51 are provided correspondingly to the light-emitting structure 31, and the first electrode 41 and the second electrode 51 jointly drive and control whether the light-emitting structure 31 emits light or not. Illustratively, the first electrode 41 is a cathode and the second electrode 51 is an anode.

Optionally, the display panel further includes a first electrode layer 40. The first electrode layer 40 is positioned on a side of the light-emitting functional layer facing away from the substrate 10. Further, the display panel further include a second electrode layer 50 positioned on a side of the light-emitting functional layer facing the substrate 10. The first electrode layer 40 is provided with first electrode(s) 41, and the second electrode layer 50 is provided with second electrode(s) 51. There may be a plurality of second electrodes 51 that are arranged correspondingly to the light-emitting structures 31. The first electrode(s) 41 and the second electrode(s) 51 jointly drive and control whether the light-emitting structures 31 emit light or not. Illustratively, the first electrode(s) 41 are cathode(s) and the second electrode(s) 51 are anode(s).

The isolation structures 20 can enclose to form a plurality of opening structures 21. Illustratively, an orthographic projection of the isolation structures 20 on the substrate 10 is in the form of a net-like structure. The multiple light-emitting structures 31 are respectively provided in the plurality of opening structures 21, namely, orthographic projections of the light-emitting structures 31 on the substrate 10 are arranged correspondingly to orthographic projections of the opening structures 21 on the substrate 10, and the orthographic projections of the light-emitting structures 31 on the substrate 10 are at least partially positioned in the orthographic projections of the opening structures 21 on the substrate 10. Further, during the fabrication of the light-emitting functional layer, a precision metal photomask may be eliminated due to the presence of the isolation structure 20.

Specifically, the red light-emitting structure 31 before the preparation of the green light-emitting structure 31 is taken as an example. Since the precision metal photomask is eliminated, a red light-emitting material corresponding to the red light-emitting structure 31 firstly falls into the respective opening structures 21, and then a part of the red light-emitting material in the opening structures 21 is selectively etched away and the other part of the red light-emitting material in the opening structures 21 remains to form the red light-emitting structure 31. After that, a green light-emitting material corresponding to the green light-emitting structure 31 falls into the respective opening structures 21, and then apart of the green light-emitting material in the opening structure 21 is selectively etched away and the other part of the green light-emitting material in the opening structure 21 remains to form the green light-emitting structure 31.

Similarly, due to the presence of the isolation structure 20, the first electrode layer 40 may also include a plurality of first electrodes 41 provided respectively in the opening structures 21, namely, the plurality of first electrodes 41 may be arranged correspondingly to the plurality of light-emitting structures 31 so as to achieve drive control over the light-emitting structures 31.

A variety of other film layer structures are contained in the display panel. Some of the film layers have a certain fluidity due to factors such as material compositions and the like. In order to achieve an effective cut-off for such film layer structures, the display panel in the embodiments of the present application is further provided with the blocking portion 90 positioned in the second area A2, which mainly serves to block and reduce the probability of some of the film layers flowing to a side of the blocking portion 90 facing away from the first area A1, so as to improve the reliability of the internal structure of the display panel.

In general, a film layer structure having fluidity itself has a certain thickness dimension, and the thickness of such a film layer structure gradually decreases as it approaches an edge position of a display panel. On this basis, if the blocking portion 90 is provided at a position closer to the first area A1, it is necessary to provide a larger dimension of the blocking portion 90 in the thickness direction Z to satisfy the requirement for blocking, but this is not conducive to the overall thickness design of the display panel. In view of this, the blocking portion 90 is generally positioned on a remote position from the first area A1, and further, in the related art, the blocking portion 90 may be positioned on a side of the gate driving circuit facing away from the first area A1.

The gate driving circuit is positioned in the second area A2, and the blocking portion 90 is positioned on the side of the gate driving circuit facing away from the first area A1, namely, the blocking portion 90 is spaced apart from the gate driving circuit in a direction parallel to the plane of the substrate 10. An orthographic projection of the blocking portion 90 on the substrate 10 is adjacent to an orthographic projection of the gate driving circuit on the substrate 10.

However, in the embodiments of the present application, since the isolation structure 20 encloses to form the plurality of opening structures 21, and at least some of the opening structures 21 can be used for accommodating a film layer structure having fluidity, the presence of the isolation structure 20 can reduce thickness dimensions of some of the film layers in the second area A2. On this basis, the embodiments of the present application can appropriately move the blocking portion 90 in the direction towards the first area A1, so that at least a part of the blocking portion 90 is positioned on a side of the gate driving circuit facing away from the substrate 10, without excessively increasing the height of the blocking portion 90, which helps to alleviate the problem that the bezel size of the display panel is too large due to a too large distance between the blocking portion 90 and the first area A1, helping to reduce the bezel size of the display panel and improve the display effect.

Further optionally, at least a part of the blocking portion 90 may be positioned on a side of the light-emitting control circuit D2 facing away from the substrate 10.

It should be noted that the blocking portion 90 can be positioned entirely on the side of the light-emitting control circuit D2 facing away from the substrate 10; alternatively, a part of the blocking portion 90 can be positioned on the side of the light-emitting control circuit D2 facing away from the substrate 10, and another part of the blocking portion 90 can be positioned on a side of the light-emitting control circuit D2 close to the first area A1; alternatively, a part of the blocking portion 90 can be positioned on the side of the light-emitting control circuit D2 facing away from the substrate 10, and another part of the blocking portion 90 can be positioned on a side of the light-emitting control circuit D2 far away from the first area A1, which is not limited in the embodiments of the present application. Since the light-emitting control circuit D2 itself has a certain thickness dimension, the presence of the light-emitting control circuit D2 helps to reduce the height dimension of at least a partial structure of the blocking portion 90 positioned on the side of the light-emitting control circuit D2 facing away from the substrate 10, thereby reducing the material cost corresponding to the blocking portion 90, and providing a strong practicality.

In some embodiments, the display panel further includes a second encapsulation layer 72 arranged on a side of the light-emitting functional layer facing away from the substrate 10, and the second encapsulation layer 72 includes an organic material. A part of the second encapsulation layer 72 may be positioned within the opening structures 21.

The second encapsulation layer 72 is positioned on the side of the light-emitting functional layer facing away from the substrate 10, namely, on the light-emitting surface side of the light-emitting structure 31. The second encapsulation layer 72 is partially positioned in the first area A1 and partially positioned in the second area A2. The second encapsulation layer 72 is mainly used for encapsulating and protecting the light-emitting structures 31, so as to reduce the risk of water and oxygen intrusion into the light-emitting structures 31, and improving the light-emitting reliability of the display panel.

The second encapsulation layer 72 includes an organic material, and has a certain fluidity; however, since the second encapsulation layer 72 can be partially positioned in the opening structures 21, the opening structures 21 can play a certain role of accommodating overflow for the second encapsulation layer 72, so that the thickness dimension of the second encapsulation layer 72 at the second area A2 is reduced, and in turn the distance between the blocking portion 90 and the first area A1 can be reduced to enable at least a part of the blocking portion 90 to be positioned on the side of the light-emitting control circuit D2 facing away from the substrate 10, which helps to achieve a narrow-bezel display effect of the display panel.

In some embodiments, the display panel further includes a first encapsulation layer 71 arranged between the second encapsulation layer 72 and the light-emitting functional layer, and a third encapsulation layer 73 positioned on a side of the second encapsulation layer 72 facing away from the substrate 10. The first encapsulation layer 71 and the third encapsulation layer 73 includes inorganic materials.

The first encapsulation layer 71 and the third encapsulation layer 73 are respectively positioned on two sides of the second encapsulation layer 72 in the thickness direction Z, and the first encapsulation layer 71, the second encapsulation layer 72 and the third encapsulation layer 73 jointly form a thin film encapsulation structure, thereby improving the encapsulation and protection effect on the light-emitting functional layer. The first encapsulation layer 71 and the third encapsulation layer 73 both include inorganic materials, and the first encapsulation layer 71 and the third encapsulation layer 73 can play a role of limiting and blocking the second encapsulation layer 72.

Further optionally, the first encapsulation layer 71 includes a plurality of first encapsulation portions 711 respectively provided in the opening structures 21. The first encapsulation portions 711 and the blocking portion 90 are arranged at intervals in a direction parallel to the plane of the substrate 10.

Due to the presence of the isolation structure 20, the encapsulation material used to form the first encapsulation portion 711 may also fall into the opening structures 21, thereby forming a plurality of first encapsulation portions 711 arranged correspondingly to the opening structures 21. Different first encapsulation portions 711 are arranged at intervals from each other.

In the embodiments of the present application, due to the presence of the blocking portion 90, the blocking portion 90 can block overflowing for the second encapsulation layer 72, thereby reducing the risk of the second encapsulation layer 72 extending to the side of the blocking portion 90 facing away from the first area A1, and improving the encapsulation reliability of the display panel.

In some embodiments, a part of the third encapsulation layer 73 is positioned on a side of the blocking portion 90 facing away from the substrate 10, that is, the third encapsulation layer 73 may extend from the first area A1 into the second area A2 and cover at least a partial structure of the blocking portion 90.

Under this design, the blocking portion 90 may cooperate with the third encapsulation layer 73 so as to jointly play a role of limiting and blocking for the second encapsulation layer 72, further reducing the risk of the second encapsulation layer 72 extending to the side of the blocking portion 90 facing away from the first area A1, and improving the encapsulation reliability of the display panel.

In some embodiments, as shown in FIG. 2, the display panel further includes a scanning driving circuit D1 positioned between the light-emitting control circuit D2 and the first area A1. The blocking portion 90 is positioned on a side of the scanning driving circuit D1 facing away from the first area A1.

The scanning driving circuit D1 may include multiple stages of shift registers cascaded with each other, which may sequentially output conduction levels so as to sequentially scan each row of pixel circuits positioned in the first area A1 to satisfy the display requirement.

The scanning driving circuit D1 and the light-emitting control circuit D2 are both positioned in the second area A2, and the scanning driving circuit D1 is positioned at a side of the light-emitting control circuit D2 close to the first area A1. The distance between the scanning driving circuit D1 and the first area A1 is relatively short. On this basis, in order to ensure the blocking overflow effect of the blocking portion 90 on the first encapsulation layer 71, the embodiments of the present application arrange the blocking portion 90 on a side of the scanning driving circuit D1 facing away from the first area A1, namely, the distance between the blocking portion 90 and the first area A1 is greater than the distance between the scanning driving circuit D1 and the first area A1. This ensures a certain distance between the blocking portion 90 and the first area A1, thereby increasing the effect for blocking overflowing of the blocking portion 90 on the first encapsulation layer 71 without increasing the height dimension of the blocking portion 90.

In some embodiments, the display panel further includes a second insulation portion 91 arranged between the light-emitting control circuit D2 and at least a part of the blocking portion 90.

The second insulation portion 91 may cover at least a partial structure of the light-emitting control circuit D2; for example, an orthographic projection of the second insulation portion 91 on the substrate covers an orthographic projection of the light-emitting control circuit D2 on the substrate, so that after the light-emitting control circuit D2 is prepared, the second insulation portion 91 may play a role of isolating the light-emitting control circuit D2 from the air and may also play a role of protecting the light-emitting control circuit D2 in a subsequent preparation process of a metal layer and the like, reducing the risk of over-etching of the light-emitting control circuit D2 and improving the reliability.

In addition, the second insulation portion 91 may insulate and separate the blocking portion 90 from the light-emitting control circuit D2, thereby improving the operational reliability of the light-emitting control circuit D2. It can be seen from the foregoing that the blocking portion 90 can be positioned entirely on the side of the light-emitting control circuit D2 facing away from the substrate 10, or the blocking portion 90 can also be positioned partially on the side of the light-emitting control circuit D2 facing away from the substrate 10 and partially on the side of the light-emitting control circuit D2 facing away from the first area A1. In view of this, the second insulation portion 91 may be positioned entirely on the side of the light-emitting control circuit D2 facing away from the substrate 10, or the second insulation portion 91 may be positioned partially on the side of the light-emitting control circuit D2 facing away from the substrate 10 and partially on the side of the light-emitting control circuit D2 facing away from the first area A1.

When the blocking portion 90 is positioned on the side of the light-emitting control circuit D2 facing away from the substrate 10, the first insulation portion 90 can increase the spacing between the blocking portion 90 and the substrate 10, thereby reducing the required height dimension of the blocking portion 90 and the corresponding material cost, and providing a strong practicality.

In some alternative embodiments, the orthographic projection of the blocking portion 90 on the substrate 10 is positioned within the orthographic projection of the second insulation portion 91 on the substrate 10. As such, the insulating effect of the second insulation portion 91 with respect to the blocking portion 90 and the light-emitting control circuit D2 can be further improved, thereby improving the reliability. Furthermore, due to the presence of the second insulation portion 91, the distance between the blocking portion 90 and the substrate 10 can be increased, so that the height dimension of the blocking portion 90 can be reduced and the material cost corresponding to the blocking portion 90 can be reduced.

Further optionally, the orthographic projection of the blocking portion 90 on the substrate 10 is positioned within the orthographic projection of the lighting control circuit D2 on the substrate 10.

In some embodiments, as shown in FIG. 9, the second insulation portion 91 extends from the first area A1 into the second area A2, and an orthographic projection of the second insulation portion 91 on the substrate 10 covers an orthographic projection of the light-emitting control circuit D2 on the substrate. That is, a partial structure of the second insulation portion 91 positioned in the first area A1 is integrated with a partial structure of the second insulation portion 91 positioned in the second area A2.

In the implementation of the present application, by extending the second insulation portion 91 from the first area A1 to the second area A2, the first insulation portion can not only play the role of insulating and separating different conductive structures in the first area A1, but also play the role of covering and protecting the light-emitting control circuit D2 in the second area, thereby improving the reliability of the display panel. Further optionally, the second insulation portion 91 may be reused as a planarization layer, and the planarization layer may provide a flat surface so as to reduce the difficulty of subsequent preparation of the display panel, and may improve the preparation accuracy of the display panel, thereby providing a strong practicality.

In some embodiments, the display panel further includes first signal line(s) 60 positioned in the second area A2 and first electrode(s) 41 positioned on a side of the light-emitting structure(s) 31 facing away from the substrate. The first signal line(s) 60 are electrically connected to the first electrode(s) 41 via the isolation structure 20.

In the embodiments of the present application, the first signal line(s) 60 are not directly connected to the first electrode(s) 41, and transmit the power supply signal(s) to the respective first electrodes 41 by means of the isolation structure 20. Specifically, since the isolation structure 20 itself is arranged correspondingly to the respective first electrodes 41 and it is possible to achieve signal transmission between them, it is not necessary to extend the first signal lines 60 correspondingly to positions of the respective first electrodes 41, that is, there is no need for the first signal lines 60 to be arranged around respective first electrodes 41, as long as the first signal lines 60 are arranged on a side of the isolation structure 20 along the first direction X, and are electrically connected to the isolation structure 20. As such, power supply signals in the first signal lines 60 can be transmitted to the respective first electrodes 41 by means of the isolation structure 20, thereby satisfying the need for signal transmission. Furthermore, since the first signal lines 60 are positioned on the side of the isolation structure 20 along the first direction X, rather than in an annular structure, it contributes to reducing the bezel size of the display panel and improving the display effect.

Further, in some optional embodiments, the first signal line 60 is positioned on a side of the isolation structure 20 along a first direction X that is parallel to a plane of the substrate 10.

It should be noted that the embodiments of the present application do not limit the specific routing pattern of the first signal line 60. Furthermore, according to practical situations, the first signal line 60 may be positioned on one side of the isolation structure 20 completely along the first direction X, or a small number of the first signal lines 60 may be positioned on other sides of the isolation structure 20 along different directions, as long as most of the first signal lines 60 are positioned on the same side of the isolation structure 20.

In some embodiments, as shown in FIG. 2, FIG. 3, and FIG. 7, an orthographic projection of the blocking portion 90 on the substrate 10 is offset from orthographic projections of the first signal lines 60 on the substrate 10.

The blocking portion 90 is positioned in the second area A2, and the blocking portion 90 is generally positioned on an edge position of the display panel. It can be seen from the above contents that the second encapsulation layer 72 includes an organic material, and the organic material included in the second encapsulation layer 72 generally has a certain fluidity, and thus in order to reduce the risk of the organic material in the second encapsulation layer 72 overflowing, the blocking portion 90 is generally arranged on the edge position of the display panel, and the presence of the blocking portion 90 can reduce the risk of overflowing and improve the reliability of the display panel.

Further, since the first signal lines 60 are only positioned on one side of the isolation structure 20 along the first direction X, instead of being arranged around the periphery of the isolation structure 20, there may be no first signal line 60 at some positions in the second area A2. On this basis, the orthographic projection of the blocking portion 90 on the substrate 10 may be offset from the orthographic projections of the first signal lines 60 on the substrate 10, namely, the first signal lines 60 will not affect a layout design of the blocking portion 90, which helps to reduce the risk of physical interference between them.

Specific arrangement of the blocking portion 90 is not limited in the embodiments of the present application. Optionally, a partial structure of the blocking portion 90 may be positioned on at least one side of the isolation structure 20 along the second direction Y.

In some embodiments, as shown in FIG. 1-FIG. 3, the isolation structure 20 includes a first isolation portion 22 and a second isolation portion 23 stacked sequentially in a direction away from the substrate 10, and an orthographic projection of the first isolation portion 22 on the substrate 10 is positioned within an orthographic projection of the second isolation portion 23 on the substrate 10.

Specific sizes and shapes of the first isolation portion 22 and the second isolation portion 23 are not limited in the embodiments of the present application. Illustratively, a longitudinal cross-section of the isolation structure 20 may be T-shaped. This design helps to make it difficult for a light-emitting material and an electrode material to extend along the side wall of the first isolation portion 22 to the side wall of the second isolation portion 23 during the preparation of the light-emitting functional layer and the first electrode layer 40, so that the light-emitting structures 31 and first electrodes 41 in the different opening structures 21 can be prepared and separated from each other, without requiring a precision metal photomask.

Material compositions in the first isolation portion 22 and the second isolation portion 23 are not limited in the embodiments of the present application. Both the first isolation portion 22 and the second isolation portion 23 may include conductive material(s), or the first isolation portion 22 includes a conductive material, and the second isolation portion 23 includes an insulating material, as long as the first electrode(s) 41 can achieve signal transmission by means of the isolation structure 20.

Further, at least some of the first signal lines 60 are positioned within the second area A2, alternatively, the first signal lines 60 may be positioned entirely within the second area A2, or the first signal lines 60 may also extend partially into the first area A1. Similarly, the isolation structure 20 may be positioned entirely within the first area A1, or the isolation structure 20 may also extend partially into the second area A2, which is not limited in the embodiments of the present application.

In some embodiments, the first isolation portion 22 includes a conductive material and the first electrodes 41 are electrically connected to the first isolation portion 22.

The first signal lines 60 may transmit power supply signals to the first electrode 41 via the first isolation portion 22. The first electrodes 41 may be in direct contact with the first isolation portion 22, or the first electrodes 41 may be electrically connected to the first isolation portion 22 via another conductive structure, which is not limited in the embodiments of the present application.

In the embodiment of the present application, by providing a conductive material in the first isolation portion 22, the first signal lines 60 can transmit the power supply signals to the first electrodes 41 via the first isolation portion 22, thereby satisfying the need for signal transmission. Further, by setting a path along which the first isolation portion 22 extends in the first area A1, the first isolation portion 22 can extend to the whole range of the first area A1, and it is in turn that the first signal lines 60 are only needed to be arranged on one side of the isolation structure 20 along the first direction X, instead of being arranged around the first area A1, thereby reducing the display panel's bezel size.

A position relationship between the first signal lines 60 and the first isolation portion 22 is not limited in the embodiments of the application. In some embodiments, at least some of the first signal lines 60 are in contact with the first isolation portion 22, i.e. the power supply signals in at least some of the first signal lines 60 may be transmitted directly into the first isolation portion 22. Further, if the isolation structure 20 further includes other conductive structures electrically connected to the first isolation portion 22, the first signal lines 60 may also be in contact with the other conductive structures.

In some embodiments, as shown FIG. 4, the isolation structure 20 further includes a third isolation portion 24 positioned on a side of the first isolation portion 22 facing the substrate 10. The third isolation portion 24 includes a conductive material and is electrically connected to the first isolation portion 22.

The isolation structure 20 includes at least the first isolation portion 22, the second isolation portion 23 and the third isolation portion 24. Sizes and shapes of the first isolation portion 22, the second isolation portion 23 and the third isolation portion 24 are not limited in the embodiments of the present application. Illustratively, the orthographic projection of the first isolation portion 22 on the substrate 10 is positioned within an orthographic projection of the third isolation portion 24 on the substrate 10, i.e. a longitudinal cross-section of the first isolation portion 22, the second isolation portion 23 and the third isolation portion 24 is I-shaped.

Similar to the first isolation portion 22, the third isolation portion 24 also includes a conductive material, and the first electrodes 41 can be in direct contact with the third isolation portion 24 so as to be electrically connected to the first isolation portion 22 via the third isolation portion 24. Optionally, the first electrodes 41 are overlapped with the third isolation portion 24. Further, the first electrodes 41 may be positioned partially on a side of the third isolation portion 24 facing away from the substrate 10. The arrangement of the third isolation portion 24 helps to improve the reliability of the electrical connection between the first electrodes 41 and the isolation structure 20.

In a third aspect, as shown in FIG. 7, an embodiment of the present application provides a display panel having a first area A1 and a second area A2 surrounding a periphery of the first area A1. The display panel includes a substrate 10, an isolation structure 20, a light-emitting functional layer, a light-emitting control circuit D2 and a blocking portion 90. The isolation structure 20 is arranged on a side of the substrate 10 and encloses to form a plurality of opening structures 21; the light-emitting functional layer is arranged on the side of the substrate 10 and positioned in the first area A1, the light-emitting functional layer includes a plurality of light-emitting structures 31 provided in the plurality of opening structures 21 respectively, and at least one light-emitting structure 31 is provided in each of the opening structures 21. For example, there is one light-emitting structure 31 in one opening structure 21, or there are multiple light-emitting structures 31 emitting the same color in one opening structure 21.

The light-emitting control circuit D2 is positioned in the second area A2, the blocking portion 90 is arranged in the second area A2, and at least part of the blocking portion 90 is arranged adjacent to the light-emitting control circuit D2.

In embodiments of the present application, since the isolation structure 20 encloses to form the plurality of opening structures 21, and at least some of the opening structures 21 can be used for accommodating a film layer structure having fluidity, the presence of the isolation structure 20 can reduce thickness dimensions of some of the film layers in the second area A2. On this basis, the embodiments of the present application can appropriately move the blocking portion 90 in the direction towards the first area A1, so that at least a part of the blocking portion 90 is positioned adjacent to the light-emitting control circuit D2, without excessively increasing the height of the blocking portion 90, which helps to alleviate the problem that the bezel size of the display panel is too large due to a too large distance between the blocking portion 90 and the first area A1, helping to reduce the bezel size of the display panel and improve the display effect.

In a fourth aspect, as shown in FIG. 1-FIG. 3, an embodiment of the present application provides a display panel having a first area A1 and a second area A2, the first area A1 including a display area and the second area A2 including a bottom bezel area. The display panel includes a substrate 10, an isolation structure 20, a light-emitting functional layer and first signal lines 60. The isolation structure 20 is arranged on a side of the substrate 10 and is positioned at least in the first area A1, and the isolation structure 20 encloses to form a plurality of opening structures 21 and the isolation structure 20 includes a conductive material. The light-emitting functional layer is arranged on the side of the substrate 10 and is positioned in the first area A1, the light-emitting functional layer includes a plurality of light-emitting structures 31 respectively provided in the plurality of opening structures 21, and at least one light-emitting structure 31 is provided in each of the opening structures 21. For example, there is one light-emitting structure 31 in one opening structure 21, or there are multiple light-emitting structures 31 emitting the same color in one opening structure 21.

The first signal lines 60 are positioned on a side of the isolation structure 20 along a first direction X, the first signal lines 60 are electrically connected to the conductive material of the isolation structure 20, and the first direction X is a direction from the display area to the bottom bezel area.

In the embodiment of the present application, the first area A1 includes the display area, the second area A2 includes the bottom bezel area, and a driving chip can be provided in the bottom bezel area. The first signal lines 60 are not arranged around the first area A1, but are arranged on a side of the first area A1 along the first direction X and transmit signal(s) to different positions of the first area A1 by means of the isolation structure 20. This satisfies the need for signal transmission. Furthermore, since the first signal lines 60 are positioned on the side of the isolation structure 20 along the first direction X, instead of being in a ring-shaped structure, it helps to reduce the bezel size of the display panel and improve the display effect.

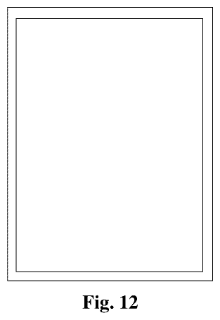

In a fifth aspect, as shown in FIG. 12, an embodiment of the present application provides a display device including the display panel according to any one of the preceding embodiments.

It should be noted that display device according to the embodiment of the present application has the advantageous effects of the display panel in any one of the preceding embodiments, and the details thereof are described in the foregoing description of the advantageous effects of the display panels, and will not be detailed in the embodiment of the present application.

While the implementations of the present application are disclosed above, the foregoing is only for purpose of illustration of the implementations of the present application applied in the present application and is not intended to limit the present application. Modifications and variations in forms and details may be made by any person skilled in the art related to the present application, without departing from the gist and scope disclosed in the present application, and the protection scope of the present application is defined only by the scope of the appended claims.

The above provides only specific implementations of the present application, it is apparent to those skilled in the related art that other alternatives of the above connections may be obtained by referring to the corresponding processes in the foregoing method embodiments, which will not be repeated herein for the convenience and brevity of the description. It should be understood that the protection scope of the present application is not limited to this, and any person skilled in the art can easily conceive of various equivalent modifications or alternatives within the technical scope disclosed in the present application, and these modifications or alternatives should all be covered within the protection scope of the present application.

What is claimed is:

1. A display panel having a first area, the display panel comprising:
a substrate;
an isolation structure arranged on a side of the substrate and positioned at least in the first area, the isolation structure enclosing to form a plurality of opening structures, and the isolation structure including a conductive material;
a light-emitting functional layer arranged on the side of the substrate and positioned in the first area, the light-emitting functional layer including a plurality of light-emitting structures respectively provided in the plurality of opening structures; and
first signal lines positioned on a side of the isolation structure along a first direction, the first signal lines being electrically connected to the conductive material of the isolation structure, and the first direction being parallel to a plane of the substrate.

2. The display panel of claim 1, wherein the isolation structure includes a first isolation portion and a second isolation portion stacked sequentially in a direction away from the substrate, and an orthographic projection of the first isolation portion on the substrate is positioned within an orthographic projection of the second isolation portion on the substrate;
the display panel further comprises a first electrode layer arranged on a side of the light-emitting functional layer facing away from the substrate, the first electrode layer including a plurality of first electrodes respectively provided in the plurality of opening structures;
the first electrodes are electrically connected to the first signal lines via the isolation structure;
the first isolation portion includes a conductive material and is electrically connected to the first electrodes;
at least some of the first signal lines are in contact with the first isolation portion;
the isolation structure further includes a third isolation portion positioned on a side of the first isolation portion facing the substrate, and the third isolation portion includes a conductive material and is electrically connected to the first isolation portion; and
the first electrodes are overlapped with the third isolation portion.

3. The display panel of claim 2, wherein the second isolation portion includes a conductive material;
the first isolation portion is electrically connected to the second isolation portion, and at least some of the first signal lines are in contact with the second isolation portion;
an insulation structure further includes a first insulation portion arranged between the first isolation portion and the second isolation portion; and
an etching selectivity ratio of the first isolation portion to the second isolation portion is greater than 1.

4. The display panel of claim 1, further having a second area surrounding a periphery of the first area,
the display panel further comprising a driving chip arranged in the second area and positioned on the side of the isolation structure along the first direction, the first signal lines being electrically connected to the driving chip;
the second area including a first subarea and a second subarea positioned between the driving chip and the isolation structure, and the first subarea and the second subarea being arranged side by side in a second direction set to intersect the first direction,
wherein first signal lines of the first signal lines positioned in the first subarea and first signal lines of the first signal lines positioned in the second subarea are insulated from each other.

5. The display panel of claim 1, wherein the isolation structure includes a first isolation structure and a second isolation structure that are mutually insulated, the first isolation structure and the second isolation structure are positioned in different subareas in the first area, and the first isolation structure and the second isolation structure have different resistances in an identical orthographic projection area; and
the first isolation structure and the second isolation structure are electrically connected to different ones of the first signal lines respectively.

6. The display panel of claim 5, wherein orthographic projection areas of the first isolation structure and the second isolation structure on the substrate are different;
cross-sectional dimensions of the first isolation structure and the second isolation structure are different;
the first isolation structure is spaced apart from the second isolation structure; and
the isolation structure further includes an insulation structure positioned between the first isolation structure and the second isolation structure.

7. The display panel of claim 1, further having a second area surrounding a periphery of the first area,
the display panel further comprising a blocking portion arranged in the second area, an orthographic projection of a structure of the blocking portion positioned on both sides of the first area along a second direction on the substrate not overlapping with orthographic projections of the first signal lines on the substrate, and the second direction being set to intersect the first direction;
the display panel further comprising a first encapsulation layer arranged on a side of the light-emitting functional layer facing away from the substrate, and an orthographic projection of the first encapsulation layer on the substrate not overlapping with the orthographic projection of the blocking portion on the substrate; and
the display panel further comprising a third encapsulation layer arranged on a side of the first encapsulation layer facing away from the substrate, and the third encapsulation layer being positioned on a side of the blocking portion facing away from the substrate and covering at least a part of the blocking portion.

8. The display panel of claim 7, further comprising a gate driving circuit positioned in the second area, at least a part of the blocking portion being positioned on a side of the gate driving circuit facing away from the substrate; and
the gate driving circuit including a light-emitting control circuit, and at least a part of the blocking portion is positioned on a side of the light-emitting control circuit facing away from the substrate.

9. The display panel of claim 8, further comprising a second encapsulation layer positioned on a side of the light-emitting functional layer facing away from the substrate, the second encapsulation layer including an organic material;
the display panel further comprising a first encapsulation layer arranged between the second encapsulation layer and the light-emitting functional layer, and a third encapsulation layer positioned on a side of the second encapsulation layer facing away from the substrate, the first encapsulation layer and the third encapsulation layer including inorganic materials;
the first encapsulation layer including a plurality of first encapsulation portions respectively provided in the opening structures, the first encapsulation portions and the blocking portion being arranged at intervals in a direction parallel to the plane of the substrate; and
a part of the third encapsulation layer being positioned on a side of the blocking portion facing away from the substrate.

10. The display panel of claim 8, wherein the gate driving circuit further includes a scanning driving circuit positioned between the light-emitting control circuit and the first area;
the blocking portion is positioned on a side of the scanning driving circuit facing away from the first area; or the blocking portion is positioned on a side of the scanning driving circuit facing away from the substrate; and
an orthographic projection of the blocking portion on the substrate is positioned within an orthographic projection of the light-emitting control circuit on the substrate; or, an orthographic projection of the blocking portion on the substrate at least partially overlaps with an orthographic projection of the light-emitting control circuit on the substrate; or, an orthographic projection of the blocking portion on the substrate at least partially is offset from and adjacent to an orthographic projection of the light-emitting control circuit on the substrate.

11. The display panel of claim 8, further comprising a second insulation portion arranged between the light-emitting control circuit and at least a part of the blocking portion;
an orthographic projection of the blocking portion on the substrate is positioned within an orthographic projection of the second insulation portion on the substrate;
the second insulation portion extends from the first area into the second area, and an orthographic projection of the second insulation portion on the substrate covers an orthographic projection of the light-emitting control circuit on the substrate; and
the second insulation portion is positioned in a planarization layer.

12. The display panel of claim 8, wherein the blocking portion includes a plurality of blocking posts arranged at intervals, and at least some of the blocking posts are positioned on a side of the light-emitting control circuit facing away from the substrate;
the blocking posts are all positioned on a side of the light-emitting control circuit facing away from the substrate; or, some of the blocking posts are positioned on the side of the light-emitting control circuit facing away from the substrate; and
a number of the blocking posts is greater than 2.

13. The display panel of claim 7, further comprising a light-emitting control circuit positioned in the second area, at least a part of the blocking portion being positioned on a side of the light-emitting control circuit facing away from the substrate, or the blocking portion is adjacent to the light-emitting control circuit; and
the display panel further comprising a second insulation portion positioned between the blocking portion and the light-emitting control circuit.

14. The display panel of claim 7, further comprising a pixel definition layer, the isolation structure being arranged on a side of the pixel definition layer facing away from the substrate or the isolation structure being arranged in holes in the pixel definition layer, the pixel definition layer including a pixel defining portion and pixel openings defined by the pixel defining portion, and at least a part of each light-emitting structure is positioned in a corresponding pixel opening;
a part of the pixel definition layer being positioned on a side of the blocking portion facing away from the substrate;
the pixel definition layer extending from the first area into the second area;
an orthographic projection of a light-emitting control circuit on the substrate being positioned within an orthographic projection of the pixel definition layer on the substrate, or an orthographic projection of the blocking portion on the substrate being positioned within an orthographic projection of an outer edge of the pixel definition layer on the substrate; and
the pixel definition layer including an inorganic material.

15. A display panel having a first area and a second area surrounding a periphery of the first area, the display panel comprising:
a substrate;
an isolation structure arranged on a side of the substrate, the isolation structure enclosing to form a plurality of opening structures;
a light-emitting functional layer arranged on the side of the substrate and positioned in the first area, the light-emitting functional layer including a plurality of light-emitting structures respectively provided in the plurality of opening structures;
a gate driving circuit positioned in the second area; and
a blocking portion arranged in the second area, and at least a part of an orthographic projection of the blocking portion on the substrate overlaps with an orthographic projection of the gate driving circuit on the substrate.

16. The display panel of claim 15, further comprising a second encapsulation layer arranged on a side of the light-emitting functional layer facing away from the substrate, the second encapsulation layer including an organic material and is partially positioned in the opening structures;
the display panel further comprising a first encapsulation layer arranged between the second encapsulation layer and the light-emitting functional layer, and a third encapsulation layer positioned on a side of the second encapsulation layer facing away from the substrate, the first encapsulation layer and the third encapsulation layer including inorganic materials;
the first encapsulation layer including a plurality of first encapsulation portions respectively provided in the opening structures, the first encapsulation portions and the blocking portion being arranged at intervals in a direction parallel to a plane of the substrate; and
a part of the third encapsulation layer being positioned on a side of the blocking portion facing away from the substrate.

17. The display panel of claim 15, wherein the gate driving circuit includes a light-emitting control circuit, an orthographic projection of at least a part of the blocking portion on the substrate overlaps with an orthographic projection of the light-emitting control circuit on the substrate;
the gate driving circuit further includes a scanning driving circuit positioned between the light-emitting control circuit and the first area;
the blocking portion is positioned on a side of the scanning driving circuit facing away from the first area;
the display panel further comprises a third insulation portion arranged between the light-emitting control circuit and at lease a part of the blocking portion;
an orthographic projection of the blocking portion on the substrate is positioned within an orthographic projection of the third insulation portion on the substrate;
the third insulation portion extends from the first area into the second area, and an orthographic projection of the third insulation portion on the substrate covers the orthographic projection of the light-emitting control circuit on the substrate; and
the third insulation portion is positioned in a planarization layer.

18. The display panel of claim 15, further comprising first signal lines positioned in the second area, and first electrodes positioned on a side of the light-emitting structure facing away from the substrate, the first signal lines being electrically connected to the isolation structure;
the first signal lines being positioned on a side of the isolation structure and along a first direction which is parallel to a plane of the substrate; and
an orthographic projection of the blocking portion on the substrate offsetting from orthographic projections of the first signal lines.

19. The display panel of claim 18, wherein the isolation structure includes a first isolation portion and a second isolation portion stacked sequentially in a direction away from the substrate, and an orthographic projection of the first isolation portion on the substrate is positioned within an orthographic projection of the second isolation portion on the substrate;
the first isolation portion includes a conductive material and is electrically connected to the first electrodes;
at least some of the first signal lines are connected to the first isolation portion;
the isolation structure further includes a third isolation portion positioned on a side of the first isolation portion facing the substrate, and the third isolation portion includes a conductive material and is electrically connected to the first isolation portion; and
the first electrodes are overlapped with the third isolation portion.

20. A display panel having a first area and a second area surrounding a periphery of the first area, the display panel comprising:
a substrate;
an isolation structure arranged on a side of the substrate, the isolation structure enclosing to form a plurality of opening structures;
a light-emitting functional layer arranged on the side of the substrate and positioned in the first area, the light-emitting functional layer including a plurality of light-emitting structures respectively provided in the plurality of opening structures;
a gate driving circuit positioned in the second area; and
a blocking portion arranged in the second area, and an orthographic projection of the blocking portion on the substrate is adjacent to an orthographic projection of the gate driving circuit on the substrate.
